(19) United States
(12) Patent Application Publication
(10) Pub. No.: US 2016/0099412 A1
(43) Pub. Date: Apr. 7, 2016

(54) N-TYPE ORGANIC SEMICONDUCTOR FORMULATIONS AND DEVICES

(71) Applicants: Yuning LI, Kitchener (CA); Bin SUN, Kitchener (CA)

(72) Inventors: Yuning LI, Kitchener (CA); Bin SUN, Kitchener (CA)

(21) Appl. No.: 14/875,231

(22) Filed: Oct. 5, 2015

Related U.S. Application Data
(60) Provisional application No. 62/059,894, filed on Oct. 4, 2014.

(51) Int. Cl. H01L 51/00

(52) U.S. Cl. CPC H01L 51/0035; H01L 51/0036; H01L 51/0558

(57) ABSTRACT

The present invention discloses an organic semiconductor formulation comprising an organic semiconductor (OSC) and an organic phosphorous-containing additive (OPA) capable of enhancing the n-type performance of the organic semiconductor. The semiconductor formulation disclosed herein is suitable for producing n-type semiconductor thin films for use in a variety of electronic, optical, or optoelectronic devices such as organic thin film transistors, organic photovoltaics, and organic light emitting devices.

### CROSS REFERENCE TO RELATED APPLICATIONS

This application claims the benefit of priority of U.S. Provisional Patent Application No. 62/059,894 filed Oct. 4, 2014, which is hereby incorporated by reference.

### TECHNICAL FIELD

The present disclosure relates generally to n-type organic semiconductor formulations and devices and methods related thereto. More particularly, the present disclosure relates to an organic semiconductor formulation comprising an organic semiconductor (OSC) and an organic phosphorous-containing functional additive (OPA) capable of enhancing n-type performance of the OSC.

### BACKGROUND

Organic electronics can be manufactured at lower cost compared to conventional silicon-based electronics and are suitable for widespread applications including, but not limited to, displays, radio-frequency identification (RFID) tags, chemo/biosensors, memory devices, solar cells, photodiodes, thermoelectric devices, and batteries. In addition, organic semiconductors can be processed at low temperatures and deposited on plastic substrates to enable lightweight, flexible, and ultra-thin electronic devices. Complementary metal oxide semiconductor (CMOS) technology is widely used to realize logic circuits in various electronics. To construct CMOS-like circuits using organic semiconductors, both p-type and n-type organic semiconductors are needed for p-channel and n-channel organic thin film transistors (OTFTs), respectively. Although a number of high performance p-type organic semiconductors with high mobility greater than 0.5 cm²V⁻¹s⁻¹ (the average mobility of amorphous silicon semiconductor) have been developed, high performance n-type organic semiconductors are rare. One major challenge encountered is that many polymers that were originally targeted for n-type semiconductors turned out to be ambipolar semiconductors. An ambipolar semiconductor transports both electrons and holes, which show intrinsically high standby currents. Therefore logic circuits based on ambipolar semiconductors consume more power. Therefore there is a need to develop solution-processable n-type organic semiconductors, especially oligomers and polymers, with electron mobility greater than 0.5 cm²V⁻¹s⁻¹.

### SUMMARY

It is an object of the present disclosure to obviate or mitigate at least one disadvantage of previous organic semiconductors.

In one aspect, the present disclosure provides an n-type semiconductor formulation comprising an organic semiconductor (OSC), such as a polymeric organic semiconductor, and an organic phosphorous-containing additive (OPA) capable of enhancing n-type performance of the organic semiconductor.

In another aspect, the present disclosure provides a semiconducting layer comprising an n-type organic semiconductor formulation, the formulation comprising: an organic semiconductor (OSC); and an organic phosphorous-containing additive (OPA) capable of enhancing the electron transport performance of the organic semiconductor.

In another aspect, the present disclosure provides a method of enhancing n-type performance of an organic semiconductor, comprising mixing the OSC with an organic phosphorous-containing additive (OPA) capable of enhancing the n-type performance of the organic semiconductor to thereby form an n-type semiconductor formulation, whereby the n-type performance of the organic semiconductor is enhanced.

In another aspect, the present disclosure provides an electronic device, comprising a semiconductor layer comprising: an organic semiconductor; and an organic phosphorous-containing additive capable of enhancing the n-type performance of the organic semiconductor.

In another aspect, the present disclosure provides and organic thin film transistor comprising: a dielectric layer; a gate electrode; a semiconductor layer; a source electrode; a drain electrode, and a substrate, wherein the semiconductor layer comprises an n-type organic semiconductor formulation comprising: an organic semiconductor; and an organic phosphorous-containing additive capable of enhancing the n-type performance of the organic semiconductor.

In another aspect, the present disclosure provides a method for producing an organic semiconductor formulation comprising an organic semiconductor (OSC) and an organic phosphorous-containing additive (OPA) capable of enhancing the n-type performance of the organic semiconductor, the method comprising: a) mixing an OPA with an OSC optionally in the presence of a liquid or solvent (the first solvent); and b) optionally removing the first solvent by any suitable method such as evaporation or distillation; and c) optionally adding a second same or different solvent to dissolve or disperse the organic semiconductor formulation to any desirable concentration.

Other aspects and features of the present disclosure will become apparent to those ordinarily skilled in the art upon review of the following description of specific embodiments in conjunction with the accompanying figures.

### BRIEF DESCRIPTION OF THE DRAWINGS

Embodiments of the present disclosure will now be described, by way of example only, with reference to the attached Figures.

FIG. 1 is a typical bottom gate top contact OTFT structure.

FIG. 2 is a typical bottom gate bottom contact OTFT structure.

FIG. 3 is a typical top gate bottom contact OTFT structure.

FIG. 4 is a typical top gate top contact OTFT structure.

FIG. 5 shows the output (left) and transfer (right) characteristics of an OTFT device with OSC (3) (annealed at 50° C. for 15 minutes) in the electron accumulation and hole accumulation regimes. Channel length, L=30 μm; channel width, W=1 mm.

FIG. 6 shows the output (left) and transfer (right) characteristics of an OTFT device with OSC (3) containing 2% P(o-tolyl)₃ (tri(o-tolyl)phosphine) (annealed at 50° C. for 15 minutes) in the electron accumulation regime. L=30 μm; W=1 mm.

FIG. 7 shows the output (left) and transfer (right) characteristics of an OTFT device with OSC (3) containing 2% P(o-MeOPh)₃ (tri(o-methoxyphenyl)phosphine) (annealed at 50° C. for 15 minutes) in the electron accumulation regime. L=30 μm; W=1 mm.

FIG. 8 shows the output (left) and transfer (right) characteristics of an OTFT device with OSC (3) containing 2% (R)-BINAP ((R)-(+)-(1,1′-binaphthalene-2,2′-diyl)bis(diphenylphosphine)) (annealed at 50° C. for 15 minutes) in the electron accumulation regime. L=30 μm; W=1 mm.

### DETAILED DESCRIPTION

The present disclosure relates generally to an n-type organic semiconductor formulation and devices and methods related thereto. More particularly, the present disclosure relates to an n-type organic semiconductor formulation comprising an organic an organic semiconductor (OSC) and an organic phosphorous-containing additive (OPA) capable of enhancing n-type performance of the OSC.

The present inventors recently reported the successful conversion of p-type and ambipolar OSCs to unipolar n-type OSCs using polyethyleneimine (PEI), an organic nitrogen-containing compound, as an n-type dopant (see, Sun et al. Polyethyleneimine (PEI) as an effective dopant to conveniently convert ambipolar and p-type polymers into unipolar n-type polymers. ACS Appl. Mater. Interfaces. 2015, 7, 18662-18671, the entire contents of which is incorporated herein by reference). The PEI was combined with the OSC to provide an active semiconductor layer suitable for use in a variety of applications.

It is demonstrated herein that an organic phosphorous-containing additive (OPA), as defined herein, when combined with an OSC, can advantageously enhance n-type performance characteristics of the OSC. The OPA may be used to enhance n-type performance of n-type, ambipolar or p-type organic semiconductors, or a mixture thereof. In some embodiments, the OPA is used to enhance n-type performance of an ambipolar OSC, i.e. to convert an ambipolar OSC to a substantially n-type OSC. In some embodiments, the OPA is used to enhance n-type performance of an n-type organic semiconductor. Some n-type semiconductors show weak p-type performance. This weak p-type performance (e.g. hole transport) is problematic for certain applications where even slight hole transport behavior is detrimental. In some embodiments, the OPA can eliminate hole transport activity or reduce it to an acceptable level. In some embodiments, the OPA is used to enhance n-type performance of a p-type OSC, i.e. to convert a p-type OSC to a substantially n-type OSC. The OPAs defined herein are suitable for use with a variety of OSCs, for example, organic polymer semiconductors.

The present disclosure also relates to methods of preparing an n-type organic semiconductor formulation, an n-type semiconductor layer comprising the formulation, and electronic devices comprising the above. The n-type organic semiconductor formulation is suitable for use in multiple applications, including but not limited to organic photovoltaics (OPVs), organic thin-film transistors (OTFTs), organic light-emitting diodes (OLEDs), memory devices, photodetectors, thermoelectric devices, batteries, and sensors.

Organic P-Containing Functional Additive

The organic phosphorous-containing functional additive (OPA) comprises one or more organic phosphorous-containing compounds or moieties. The OPA comprises any suitable organic phosphorous-containing compound or moiety that is capable of enhancing n-type performance characteristics of an organic semiconductor (OSC). Without being bound by theory, it is believed that the OPA exhibits an electron-donating characteristic, which contributes to its function. It will be understood that “electron-donating” is in reference to another compound. The OPA may or may not be more electron-rich or “electron-donating” than the organic semiconductor in the formulation. In some embodiments, the OPA contributes electrons to the OSC in the operational state only (e.g. preferred in most OTFT embodiments). In some embodiments, the OPA contributes electrons to the OSC in the operational and non-operational (on and off) states (e.g. preferred in some thermoelectric and battery embodiments). A skilled person will be able to select or manufacture a suitable OPA for use in accordance with a particular application.

The OPA has the general structure PR₃, wherein each R is, independently, any suitable substituent that, when combined with the other R groups, provides an OPA that enhances n-type performance characteristics of an organic semiconductor (OSC). It is not required that each R group be an electron-donating group, as long as the overall OPA structure has a suitable electron-donating characteristic. In some embodiments, the OPA may comprise a combination of electron-donating, electron-withdrawing and/or neutral groups. It will be appreciated by persons of skill in the art that the electron-donating characteristic of the OPA can be tuned through the combination of particular R groups selected.

The PR₃ structure may be an isolated compound or may be a moiety incorporated into a polymer backbone or polymer sidechain.

In some embodiments, the OPA comprises a compound or moiety that has the general structure PR₃, wherein each R is, independently, hydrogen, hydrocarbon, substituted hydrocarbon, heteroaryl, substituted heteroaryl, alkoxy, substituted alkoxy, aryloxy, substituted aryloxy, herteroaryloxy, substituted herteroaryloxy, heteroalkyl, substituted heteroalkyl, haloalkyl, substituted haloaklyl, ester, hydroxyl, or cyano, wherein PR₃ may optionally be a moiety incorporated in the backbone of a polymer or a side chain of a polymer. In some embodiments, at least two of the three R groups of PR₃ are, independently, aryl, substituted aryl, heteroaryl, substituted heteroaryl, aryloxy, substituted aryloxy, herteroaryloxy or substituted herteroaryloxy. In some embodiments, each of the three R groups is independently, aryl, substituted aryl, heteroaryl, substituted heteroaryl, aryloxy, substituted aryloxy, herteroaryloxy or substituted herteroaryloxy. It will be understood that when PR₃ is incorporated in a polymer backbone or a polymer side chain, a hydrogen or other atom of an R group is replaced by a bond connecting the PR₃ to the polymer, or one or more R groups is part of the polymer backbone or side chain. Each of the R groups may be optionally substituted with one or more (e.g. 1, 2 or 3) suitable substituents.

In some embodiments, the OPA comprises one or more organic phosphorous-containing compounds or moieties having the general formula (I):

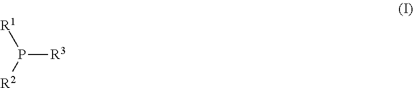

wherein:

R¹, R², and R³ are, independently, any suitable group, e.g., a group selected from H, hydroxyl (—OH), hydrocarbon, substituted hydrocarbon, heteroaryl, substituted heteroaryl, heteroalkyl, substituted heteroalkyl, alkoxy, substituted alkoxy, aryloxy, substituted aryloxy, herteroaryloxy, substituted herteroaryloxy, haloalkyl, substituted haloaklyl, —OC(═O)L, SiL₃, —OSiL₃, —N(L)SiL₃, —C(═O)OL, —C(═O)NL₂, cyano (—CN), halogen (F, Cl, Br, or I), —NL₂, —COOH and its salt form, C(O)L, —CN, —NC, —NCO, —NCS, —OCN, —SCN, —SH, —SL, —S(═O)L, —CF₃, or

a group of formula (II)

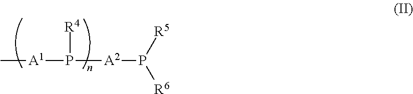

wherein R⁴, R⁵ and R⁶ are as defined above for R¹, R², and R³, or

a polymer-bound moiety selected from alkylene, substituted alkylene, alkenylene, substituted alkenylene, alkynylene, substituted alkynylene, cycloalkylene, substituted cycloalkylene, arylene, substituted arylene, heteroalkylene, substituted heteroalkylene, heteroarylene, substituted heteroarylene, arylenoxy, substituted arylenoxy, heteroarylenoxy, substituted heteroarylenoxy, biarylene, substituted biarylene, biheteroarylene, substituted biheteroarylene, biarylenoxy, substituted biarylenoxy, biheteroarylenoxy, substituted biheteroarylenoxy, oxy (—O—), —S—, and —N(L)-;

A¹ and A² are independently alkylene, substituted alkylene, alkenylene, substituted alkenylene, alkynylene, substituted alkynylene, cycloalkylene, substituted cycloalkylene, arylene, substituted arylene, heteroalkylene, substituted heteroalkylene, heteroarylene, substituted heteroarylene, heteroarylenoxy, substituted heteroarylenoxy, biarylene, substituted biarylene, biheteroarylene, substituted biheteroarylene, biarylenoxy, substituted biarylenoxy, biheteroarylenoxy, or substituted biheteroarylenoxy, oxy (—O—), —S—, and —N(L)-;

L is H, hydroxyl, hydrocarbon, substituted hydrocarbon, alkoxyl, substituted alkoxy, aryloxy, substituted aryloxy, heteroalkyl, substituted heteroalkyl, heteroaryl, substituted heteroaryl, heteroaryloxy, substituted heteroaryloxy, haloalkyl, substituted haloalkyl, a group of formula II as defined above, etc; and

n is an integer from 0 to about 1,000,000.

In some embodiments, the OPA comprises one or more organic phosphorous-containing compounds or moieties having the general formula (I):

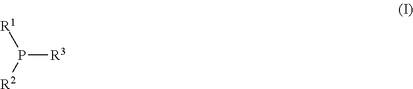

wherein:

R¹ is aryl, substituted aryl, aryloxy, substituted aryloxy, heteroaryl, substituted heteroaryl, or a polymer-bound moiety selected from a polymer-bound oxy, alkyl, substituted alkyl, alkylene, substituted alkylene, alkenylene, substituted alkenylene, alkynylene, substituted alkynylene, alkoxy, substituted alkoxy, arylene, substituted arylene, arylenoxy, substituted arylenoxy, heteroalkylene, substituted heteroalkylene, heteroarylene, substituted heteroarylene, heteroarylenoxy, or substituted heteroarylenoxy;

R² is aryl, substituted aryl, aryloxy, substituted aryloxy, heteroaryl, or substituted heteroaryl;

R³ is any suitable substituent, for example, H, aryl, substituted aryl, heteroaryl, substituted heteroaryl, alkyl, substituted alkyl, heteroalkyl, substituted heteroalkyl, alkoxy, substituted alkoxy, aryloxy or substituted aryloxy, heteroaryloxy, substituted heteroaryloxy; or

R³ is a group of formula (II):

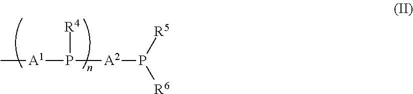

wherein R⁴, R⁵ and R⁶ are independently aryl, substituted aryl, aryloxy, substituted aryloxy, heteroaryl, substituted heteroaryl, heteroaryloxy, substituted heteroaryloxy; and

A¹ and A² are independently alkylene, substituted alkylene, alkenylene, substituted alkenylene, alkynylene, substituted alkynylene, cycloalkylene, substituted cycloalkylene, arylene, substituted arylene, heteroalkylene, substituted heteroalklene heteroarylene, substituted heteroarylene, biarylene, substituted biarylene, biheteroarylene, substituted biheteroarylene, biarylenoxy, substituted biarylenoxy, biheteroarylenoxy, or substituted biheteroarylenoxy; and

n is an integer from 0 to about 1,000,000.

In some embodiments, n is 0 to about 100,000, 0 to about 10000, 0 to about 1000, 0 to about 100, 0 to about 10, about 10, about 9, about 8, about 7, about 6, about 5, about 4, about 3, about 2, about 1 or 0.

In some embodiments, the functional additive comprises one or more organic phosphorous-containing compounds having the general formula (I):

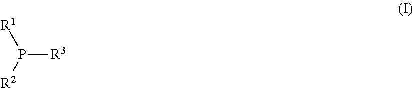

wherein:

R¹ is aryl, substituted aryl, aryloxy, substituted aryloxy, heteroaryl, substituted heteroaryl, or a polymer-bound moiety selected from a polymer-bound oxy, alkyl, substituted alkyl, alkylene, substituted alkylene, alkenylene, substituted alkenylene, alkynylene, substituted alkynylene, alkoxy, substituted alkoxy, arylene, substituted arylene, arylenoxy, substituted arylenoxy, heteroalkylene, substituted heteroalkylene, heteroarylene, substituted heteroarylene, heteroarylenoxy, or substituted heteroarylenoxy;

R² is aryl, substituted aryl, aryloxy, substituted aryloxy, heteroaryl, or substituted heteroaryl, heteroarylenoxy, or substituted heteroarylenoxy;

R³ is any suitable substituent, for example, H, aryl, substituted aryl, heteroaryl, substituted heteroaryl, alkyl, substituted alkyl, alkoxy, substituted alkoxy, aryloxy or substituted aryloxy, heteroalkylenoxy, substituted heteroalkylenoxy, heteroarylenoxy, or substituted heteroarylenoxy.

Examples of such compounds include, but are not limited to:

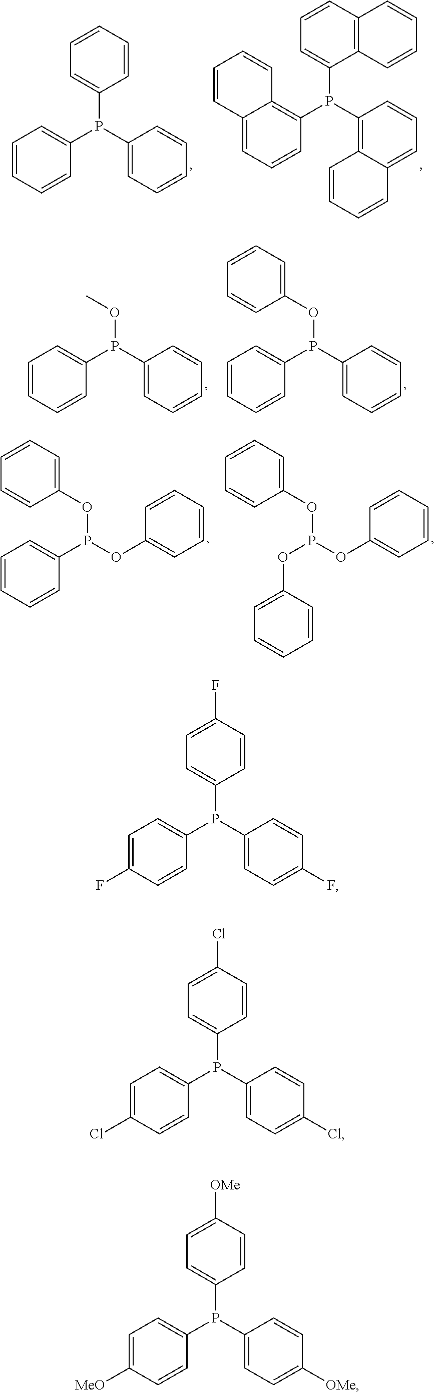

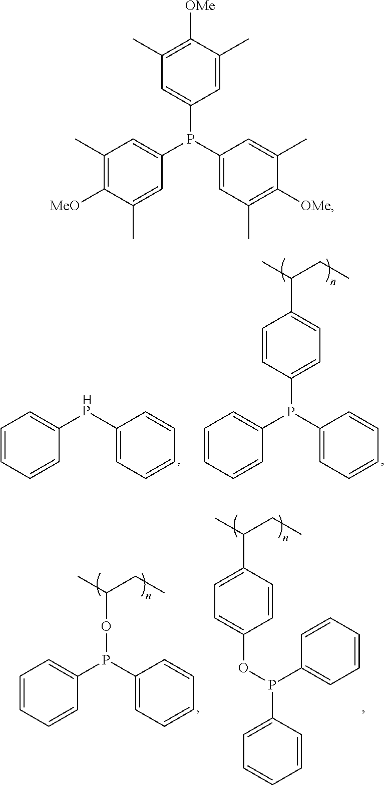

wherein n is about 1 to about 1,000,000. Each group, such as phenyl, can be optionally substituted with any suitable group, including different polymer blocks.

In some embodiments, R³ is a group of formula (II):

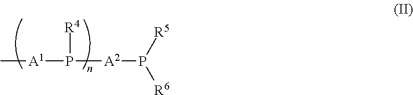

wherein R⁴, R⁵ and R⁶ are independently aryl, substituted aryl, aryloxy, substituted aryloxy, heteroaryl, substituted heteroaryl, heteroaryloxy, substituted heteroaryloxy; and

A¹ and A² are independently alkylene, substituted alkylene, alkenylene, substituted alkenylene, alkynylene, substituted alkynylene, cycloalkylene, substituted cycloalkylene, arylene, substituted arylene, heteroalkylene, substituted heteroalklene heteroarylene, substituted heteroarylene, biarylene, substituted biarylene, biheteroarylene, substituted biheteroarylene, biarylenoxy, substituted biarylenoxy, biheteroarylenoxy, or substituted biheteroarylenoxy; and

n is an integer from 0 to about 1,000,000.

Examples of such compounds where n is 0 include, but are not limited to:

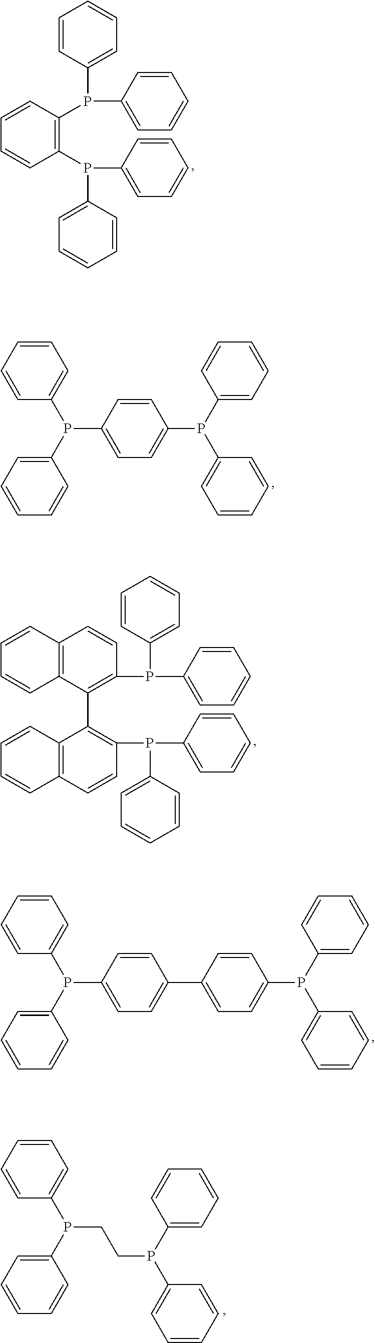 [SMILES: c1ccc(P(c2ccccc2)c2ccccc2P(c2ccccc2)c2ccccc2)cc1 ; c1ccc(P(c2ccccc2)c2ccc(P(c3ccccc3)c3ccccc3)cc2)cc1 ; c1ccc(P(c2ccccc2)c2ccc3ccccc3c2-c2c(P(c3ccccc3)c3ccccc3)ccc3ccccc23)cc1 ; c1ccc(P(c2ccccc2)c2ccc(-c3ccc(P(c4ccccc4)c4ccccc4)cc3)cc2)cc1 ; c1ccc(P(CCP(c2ccccc2)c2ccccc2)c2ccccc2)cc1]

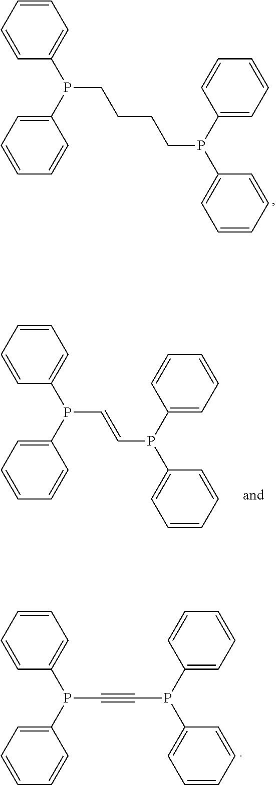 [SMILES: c1ccc(P(CCCCP(c2ccccc2)c2ccccc2)c2ccccc2)cc1 ; C(=C\P(c1ccccc1)c1ccccc1)/P(c1ccccc1)c1ccccc1 ; C(#CP(c1ccccc1)c1ccccc1)P(c1ccccc1)c1ccccc1]

Examples of such compounds wherein n is not 0 include but are not limited to:

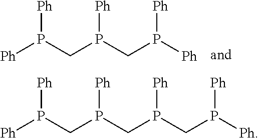

In some embodiments, the OPA is incorporated into the backbone of a polymer. In some embodiments, the OPA forms a side chain or part of a side chain on a polymer. The polymer backbone can be any suitable organic polymer, examples of which include polyethylene, polystyrene, poly(vinyl alcohol), poly(4-vinylphenol), among others. A skilled person having regard to the teaching of this disclosure will be able to select or manufacture a suitable polymer.

In some embodiments, the OPA is a polymer comprising a monomer comprising one or more moieties of the general formula (Ia):

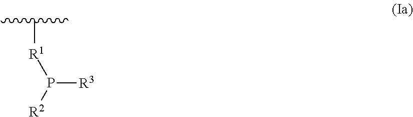

wherein: [symbol]
represents attachment to a polymer backbone;

R¹ is selected from alkylene, substituted alkylene, alkenylene, substituted alkenylene, alkynylene, substituted alkynylene, cycloalkylene, substituted cycloalkylene, arylene, substituted arylene, heteroalkylene, substituted heteroalkylene, heteroarylene, substituted heteroarylene, arylenoxy, substituted arylenoxy, heteroarylenoxy, substituted heteroarylenoxy biarylene, substituted biarylene, biheteroarylene, substituted biheteroarylene, biarylenoxy, substituted biarylenoxy, biheteroarylenoxy, or substituted biheteroarylenoxy, oxy (—O—), —S—, and —N(L)-;

R² and R³ are, independently, any suitable group, e.g., a group selected from H, hydroxyl (—OH), hydrocarbon, substituted hydrocarbon, heteroalkyl, substituted heteroalkyl heteroaryl, substituted heteroaryl, alkoxy, substituted alkoxy, aryloxy, substituted aryloxy, herteroaryloxy, substituted herteroaryloxy, haloalkyl, substituted haloaklyl, —OC(═O)L, SiL₃, —OSiL₃, —N(L)SiL₃, —C(═O)OL, —C(═O)NL₂, cyano (—CN), halogen (F, Cl, Br, or I), —NL₂, —COOH and its salt form, C(O)L, —CN, —NC, —NCO, —NCS, —OCN, —SCN, —SH, —SL, —S(═O)L, —CF₃, or

a group of formula (II)

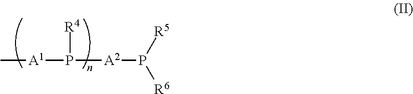

wherein R⁴, R⁵ and R⁶ are, independently, selected from any suitable group, e.g., a group selected from H, hydroxyl (—OH), hydrocarbon, substituted hydrocarbon, heteroalkyl, substituted heteroalkyl, heteroaryl, substituted heteroaryl, alkoxy, substituted alkoxy, aryloxy, substituted aryloxy, herteroaryloxy, substituted herteroaryloxy, haloalkyl, substituted haloaklyl, —OC(═O)L, SiL₃, —OSiL₃, —N(L)SiL₃, —C(═O)OL, —C(═O)NL₂, cyano (—CN), halogen (F, Cl, Br, or I), —NL₂, —COOH and its salt form, C(O)L, —CN, —NC, —NCO, —NCS, —OCN, —SCN, —SH, —SL, —S(═O)L, —CF₃, or a polymer-bound moiety selected from alkylene, substituted alkylene, alkenylene, substituted alkenylene, alkynylene, substituted alkynylene, cycloalkylene, substituted cycloalkylene, arylene, substituted arylene, heteroarylene, substituted heteroarylene, arylenoxy, substituted arylenoxy, heteroalkylene, substituted heteroalkylene, heteroarylenoxy, substituted heteroarylenoxy, biarylene, substituted biarylene, biheteroarylene, substituted biheteroarylene, biarylenoxy, substituted biarylenoxy, biheteroarylenoxy, substituted biheteroarylenoxy, oxy (—O—), —S—, and —N(L)-, or

a polymer-bound moiety selected from alkylene, substituted alkylene, alkenylene, substituted alkenylene, alkynylene, substituted alkynylene, cycloalkylene, substituted cycloalkylene, arylene, substituted arylene, heteroarylene, substituted heteroarylene, arylenoxy, substituted arylenoxy, heteroalkylene, substituted heteroalkylene, heteroarylenoxy, substituted heteroarylenoxy, biarylene, substituted biarylene, biheteroarylene, substituted biheteroarylene, biarylenoxy, substituted biarylenoxy, biheteroarylenoxy, substituted biheteroarylenoxy, oxy (—O—), —S—, and —N(L)-;

A¹ and A² are independently alkylene, substituted alkylene, alkenylene, substituted alkenylene, alkynylene, substituted alkynylene, cycloalkylene, substituted cycloalkylene, arylene, substituted arylene, heteroalkylene, substituted heteroalkylene, heteroarylene, substituted heteroarylene, heteroarylenoxy, substituted heteroarylenoxy, biarylene, substituted biarylene, biheteroarylene, substituted biheteroarylene, biarylenoxy, substituted biarylenoxy, biheteroarylenoxy, or substituted biheteroarylenoxy, oxy (—O—), —S—, and —N(L)-;

L is H, hydroxyl, hydrocarbon, substituted hydrocarbon, heteroalkyl, substituted heteroalkyl, alkoxyl, substituted alkoxy, aryloxy, substituted aryloxy, heteroaryl, substituted heteroaryl, heteroaryloxy, substituted heteroaryloxy, haloalkyl, substituted haloalkyl etc; and

n is an integer from 0 to about 1,000,000.

In some embodiments, the OPA is a polymer comprising a monomer comprising one or more moieties of the general formula (Ia):

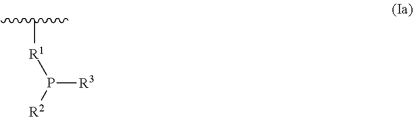

wherein:

[symbol] represents attachment to a polymer backbone;

R¹ is an oxy, alkoxy, substituted alkoxy, alkylene, substituted alkylene, alkenylene, substituted alkenylene, alkynylene, substituted alkynylene, arylene, substituted arylene, arylenoxy, or substituted arylenoxy, heteroalkylene, substituted heteroalkylene, heteroarylene, substituted heteroarylene, heteroarylenoxy, substituted heteroarylenoxy;

R² is aryl, substituted aryl, aryloxy, substituted aryloxy, heteroaryl, or substituted heteroaryl; and

R³ is any suitable substituent, for example, H, aryl, substituted aryl, heteroaryl, substituted heteroaryl, alkyl, substituted alkyl, heteroalkyl, substituted heteroalkyl, alkoxy, substituted alkoxy, aryloxy or substituted aryloxy; or

R³ is a group of formula (II):

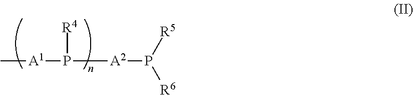

wherein R⁴, R⁵ and R⁶ are independently aryl, substituted aryl, aryloxy, substituted aryloxy, heteroaryl or substituted heteroaryl; and

A¹ and A² are independently alkylene, substituted alkylene, alkenylene, substituted alkenylene, alkynylene, substituted alkynylene, cycloalkylene, substituted cycloalkylene, arylene, substituted arylene, heteroalkylene, substituted heteroalkylene, heteroarylene, substituted heteroarylene, biarylene, substituted biarylene, biheteroarylene, substituted biheteroarylene, biarylenoxy, substituted biarylenoxy, biheteroarylenoxy, or substituted biheteroarylenoxy; and

n is an integer from 0 to about 1,000,000.

In some embodiments, the OPA compound or OPA moiety attached to a polymer is triarylphosphine (PPh₃) or a derivative thereof, wherein each aryl of triarylphosphine may independently be unsubstituted or substituted. In some embodiments, the derivative is a derivative of triarylphosphine wherein one aryl of triarylphosphine is replaced with substituted or unsubstituted heteroaryl. Preferably, the heteroaryl promotes the electron-donating characteristics of the derivative. Electron-donating characteristics of triarylphosphines and related compounds are discussed, for example, in Chevykalova et al. Electron-donating ability of triarylphosphines and related compounds studied by 31P NMR spectroscopy. Russian Chemical Bulletin January 2003, Volume 52, Issue 1, pp 78-84.

In some exemplary embodiments, the functional additive is a polymer comprising one or more repeat units selected from the group consisting of:

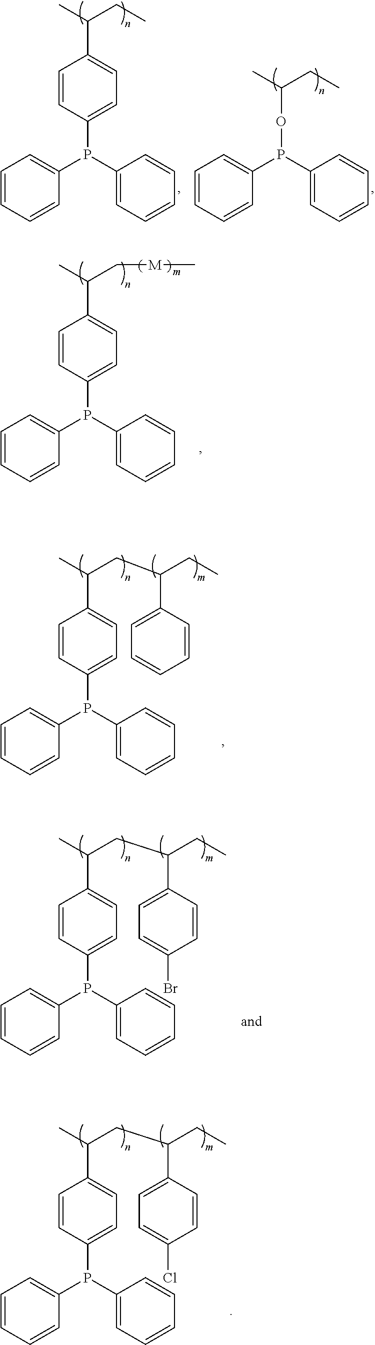

wherein

M is alkylene, methyl acrylate, methyl methacrylate, or any suitable polymer moiety,

n is an integer 1 to about 10,000

m is an integer from 0 to about 5,000;

and the number of repeat units in the polymer is between about 5 to about 10,000.

In some embodiments, the number of repeat units is about 5 to about 5000, about 5 to about 1,000, or about 5 to about 500.

Examples of functional additives suitable for use in accordance with the present disclosure include the P-containing n-type dopants disclosed in Nonoguchi, Y. et al. Systematic Conversion of Single Walled Carbon Nanotubes into n-type Thermoelectric Materials by Molecular Dopants. Sci. Rep. 2013, 3, 3344; DOI:10.1038/srep03344; and the P-containing polymers disclosed in Kristin E. Price, K. E., et al. Self-Diffusion of Linear Polymers within Microcapsules. Macromolecules 2006, 39, 7681-7685, each of which is incorporated herein by reference in its entirety.

Organic Semiconductor

The n-type semiconductor formulations of the present disclosure comprise one or more organic semiconductors. In accordance with the present disclosure, the organic semiconductor in the semiconductor formulation can be any suitable organic semiconductor having a lowest unoccupied molecular orbital (LUMO) energy level of about −3 eV or lower. In some embodiments, the semiconductor has a LUMO energy of from about −3 eV to about −5 eV, In some embodiments, the semiconductor has a LUMO energy of from about −3.5 eV to about −5 eV. In some embodiments, the semiconductor has a LUMO energy of from about −3.7 eV to about −4.5 eV.

The LUMO level may be determined by any suitable method, such as a cyclic voltammetry (CV) method using a reference such as ferrocene, using the equation: E_{LUMO} (eV)=−(E_{red}^{onset}−E_{Fc/Fc+})−4.8 eV, respectively, where E_{red}^{onset} is the onset potentials for oxidation, relative to the Ag/AgCl reference electrode, E_{Fc/Fc+} is the onset oxidation potential of ferrocene, and −4.8 eV is the highest occupied molecular orbital (HOMO) energy level of ferrocene. The LUMO level may also be determined by the HOMO level (E_{HOMO}) obtained by the CV and the optical band gap (E_{g}^{opt}) obtained by UV-VIS spectroscopy using the equation: E_{LUMO} (eV)=E_{g}^{opt}+E_{HOMO}.

The organic semiconductor may be a small molecule, an oligomer, or a polymer semiconductor. In some embodiments, the organic semiconductor comprises alternating electron donor (D) and electron acceptor (A) units. In some embodiments, the organic semiconductor is an ambipolar semiconductor. In some embodiments, the organic semiconductor is a p-type semiconductor. In some embodiments, the organic semiconductor is an n-type semiconductor. In some embodiments, the organic semiconductor is a polymer.

Where more than one OSC is used in the formulation, it is preferable that the differences between the LUMO energy levels of the OSCs are less than about 0.3 eV or more preferably less than about 0.2 eV.

Numerous organic semiconductors are known from the prior art; see, for example, WO 2008/000664, WO 2009/047104, WO 2010/049321, US 2009/0065766, EP 2009/051314, EP 2 808 373, U.S. Pat. No. 8,624,232, WO 2012/109747 A1, U.S. Pat. No. 7,902,363, U.S. Pat. No. 7,947,837, U.S. Pat. No. 8,470,961, U.S. Pat. No. 8,524,121, U.S. Pat. No. 8,613,870, U.S. Pat. No. 8,865,861, U.S. Pat. No. 9,130,171, WO 2010/136352, WO 2010/115767, WO 2014/071524, WO 2014/191358, WO 2015/139789, WO 2015/139802, Hong, W., et al. A Conjugated Polyazine Containing Diketopyrrolopyrrole for Ambipolar Organic Thin Film Transistors. Chem. Commun. 2012, 48, 8413-8415; Hong, W, et al. Dipyrrolo[2,3-b:2′,3′-e]pyrazine-2,6(1H,5H)-dione Based Conjugated Polymers for Ambipolar Organic Thin-film Transistors. Chem. Commun. 2013, 49, 484-486; Sun, B., et al. Record High Electron Mobility of 6.3 cm²V⁻¹s⁻¹ Achieved for Polymer Semiconductors Using a New Building Block. Adv. Mater. 2014, 26, 2636-2642; He, Y., et al. Branched alkyl ester side chains rendering large polycyclic (3E,7E)-3,7-bis(2-oxoindolin-3-ylidene)benzo[1,2-b:4,5-b′]difuran-2,6(3H,7H)-dione (IBDF) based donor-acceptor polymers solution-processable for organic thin film transistors. Polymer Chemistry, 2015, 6, 6689-6697; Deng, Y., et al. 3E,8E)-3,8-Bis(2-oxoindolin-3-ylidene)naphtho-[1,2-b:5,6-b′]difuran-2,7(3H,8H)-dione (INDF) based polymers for organic thin-film transistors with highly balanced ambipolar charge transport characteristics” Chem. Commun. 2015, 51, 13515-13518, each of which is incorporated herein by reference in its entirety.

A skilled person will be able to select or prepare a suitable semiconductor for use in accordance with the present disclosure based on known methods. Preparation of polymeric semiconductors is described, for example, in WO 2014/071524, Sakamoto, J., et al. Suzuki polycondensation: Polyarylenes a la carte. Macromol. Rapid Commun. 2009, 30, 653-687; Carsten, B.; He, F.; Son, H. J.; Xu, T.; Yu, L. Stille polycondensation for synthesis of functional materials. Chem. Rev. 2011, 111, 1493-1528; Mercier, L. G. and Leclerc, M. Direct (Hetero)Arylation: A New Tool for Polymer Chemists. Acc. Chem. Res., 2013, 46 (7), pp 1597-1605, among others, each of which is incorporated herein by reference in its entirety.

Exemplary organic semiconductors include polymers comprising repeat units selected from, but not restricted to, one or more of the following:

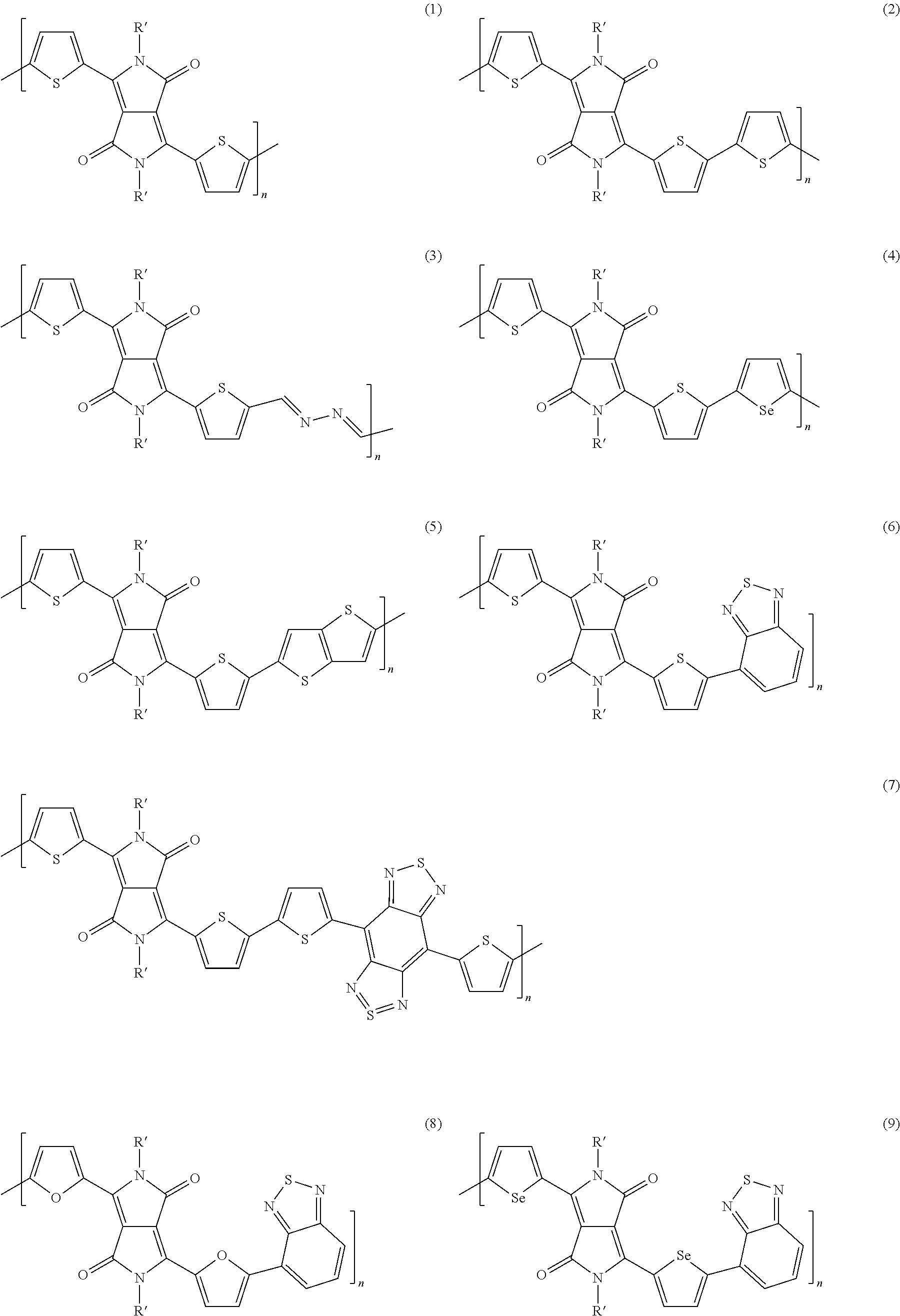

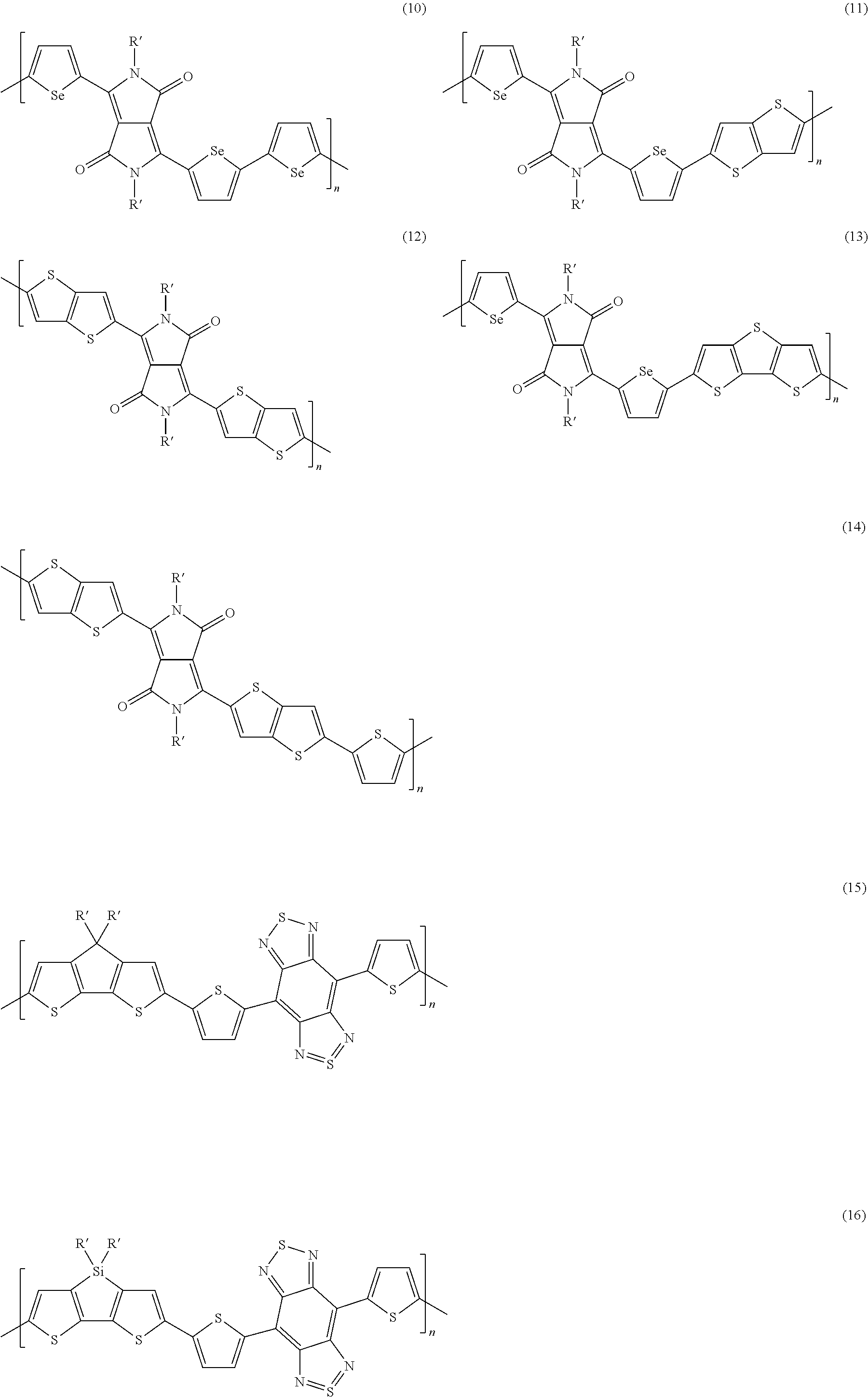

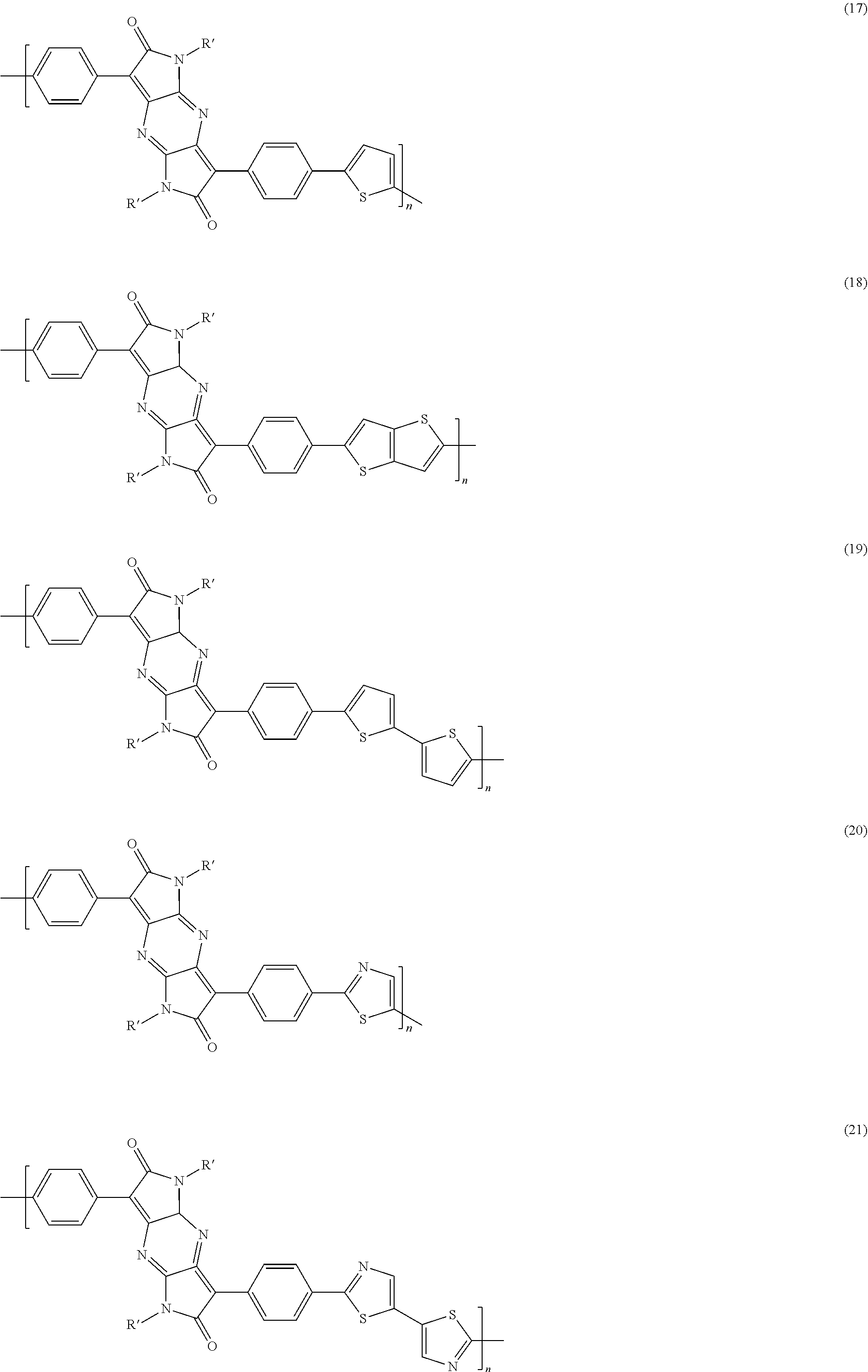

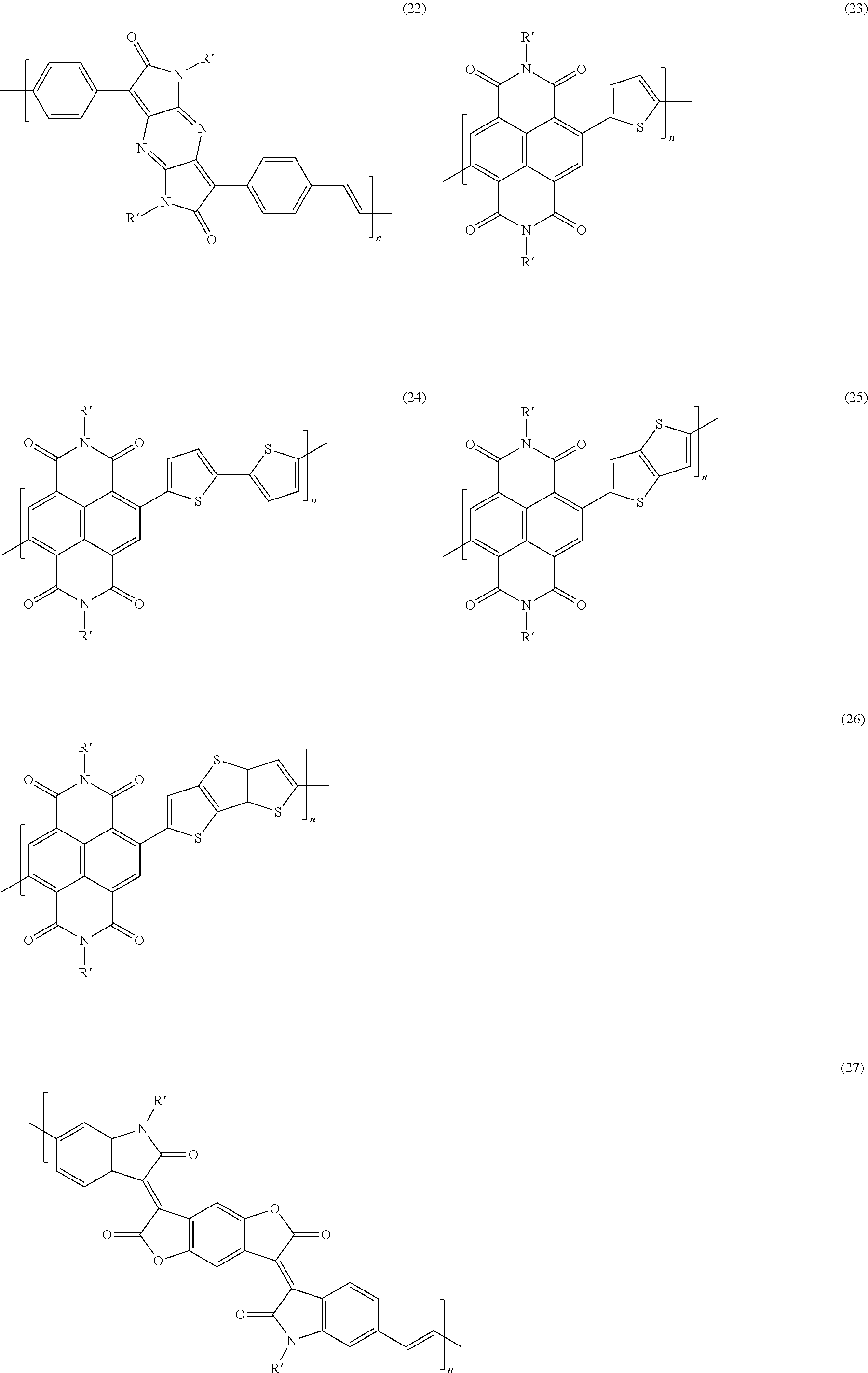

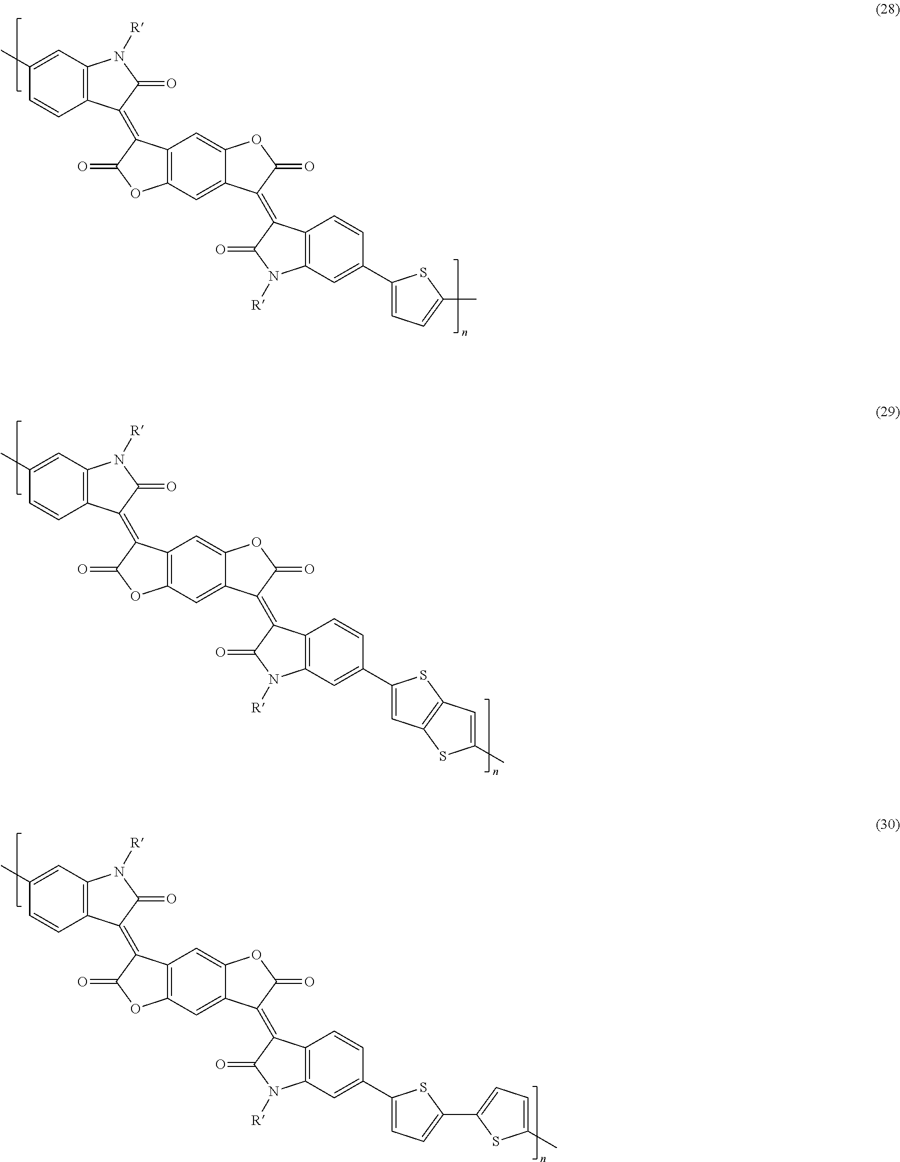

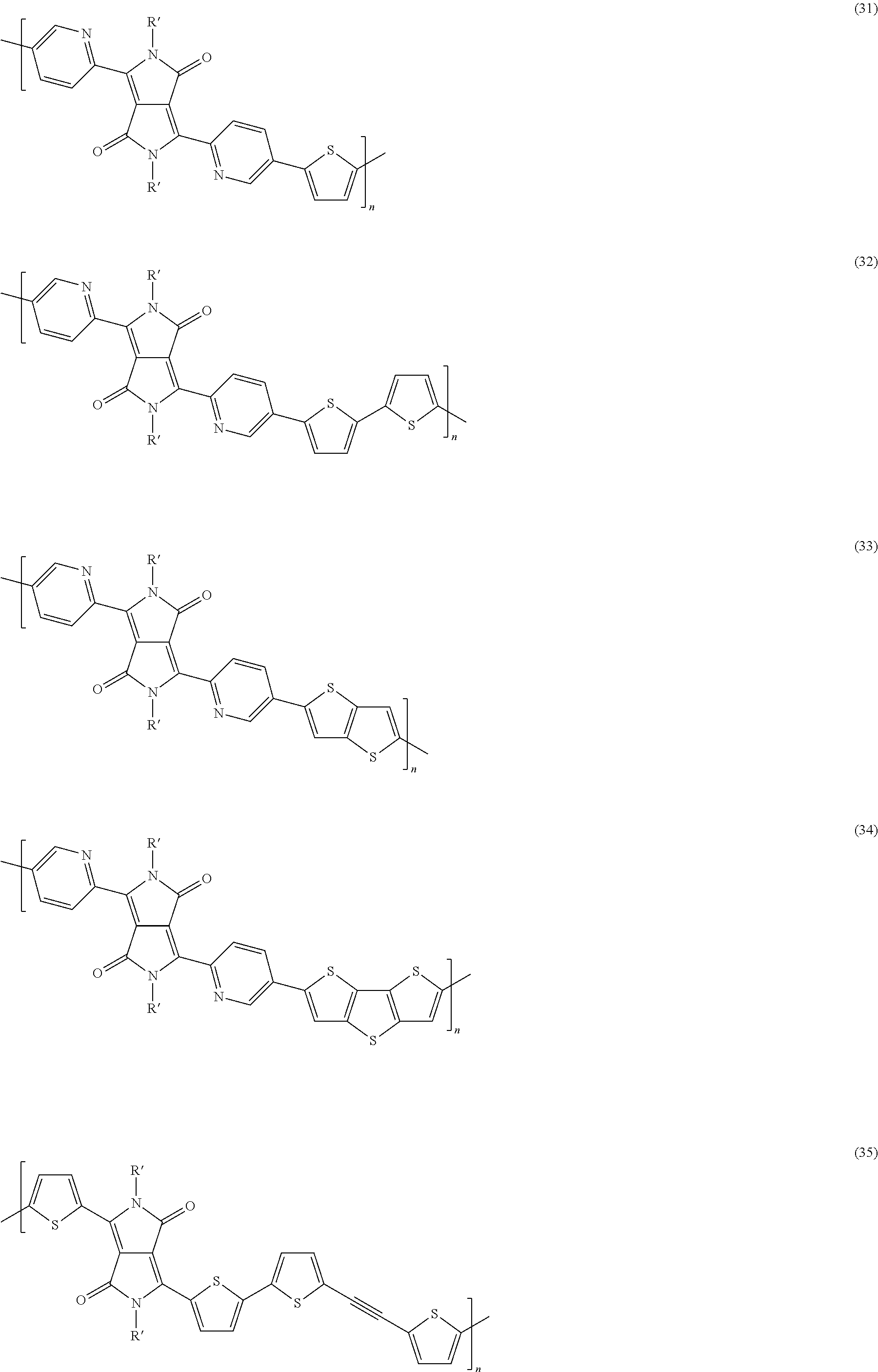

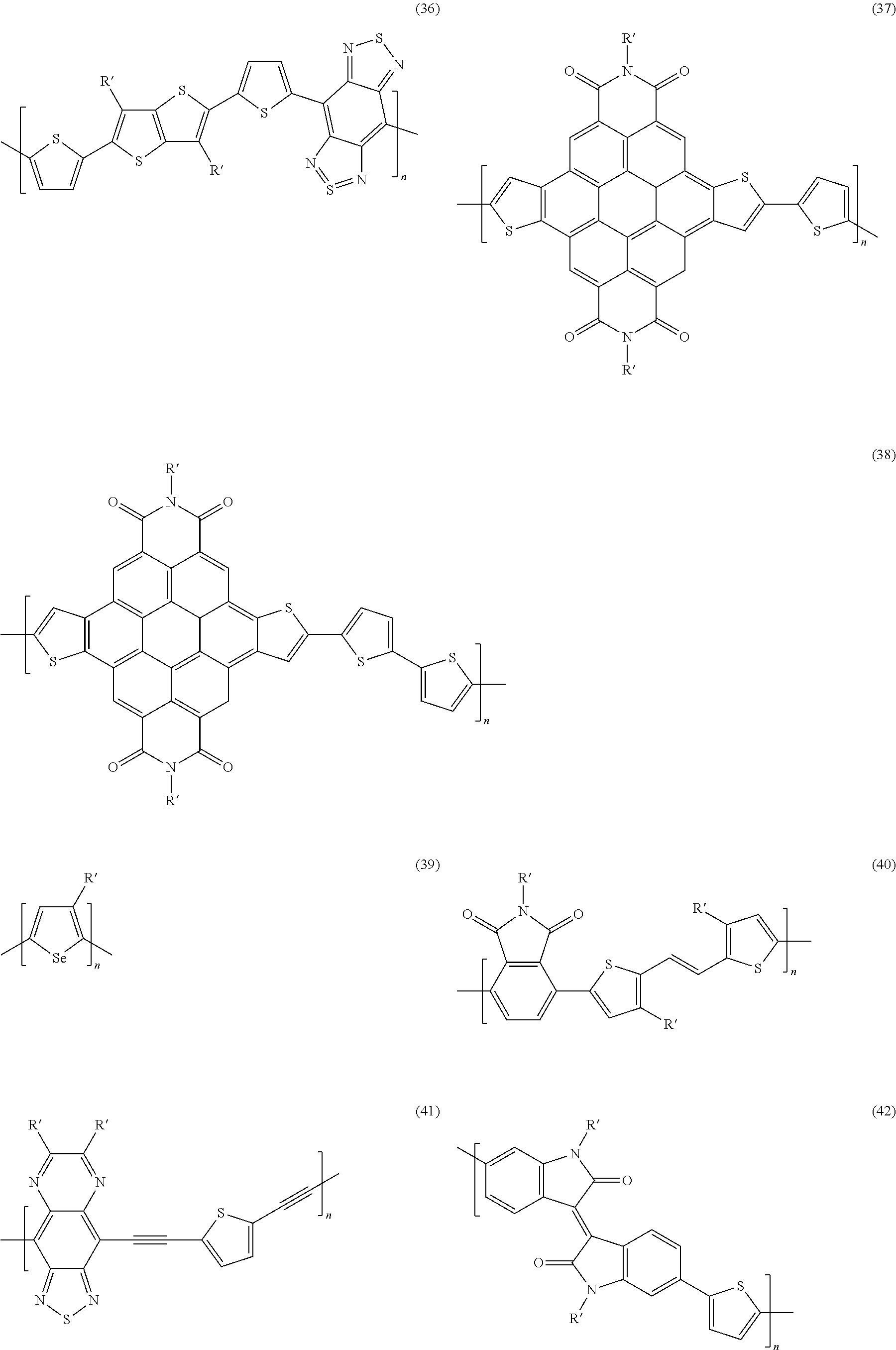

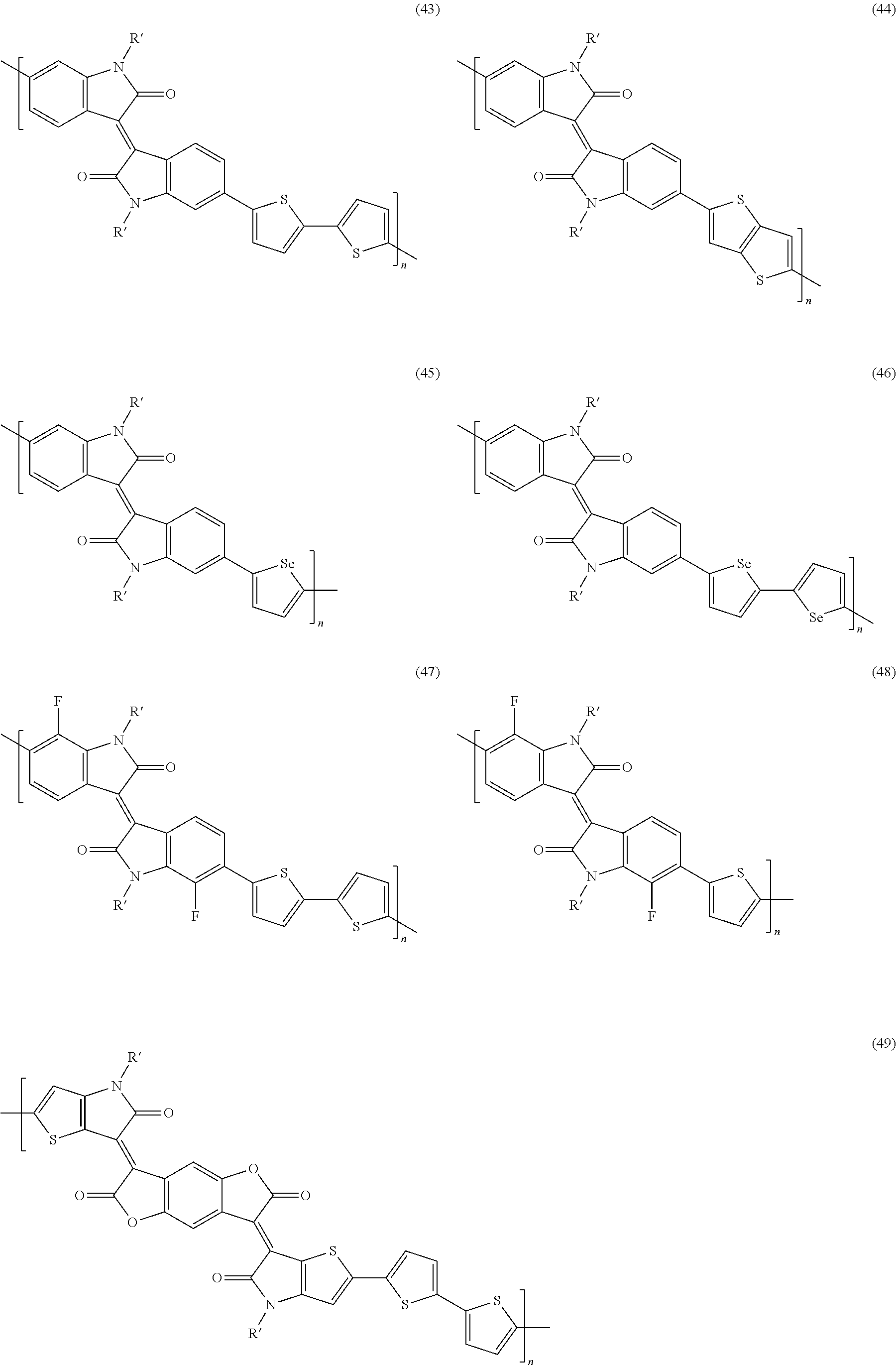

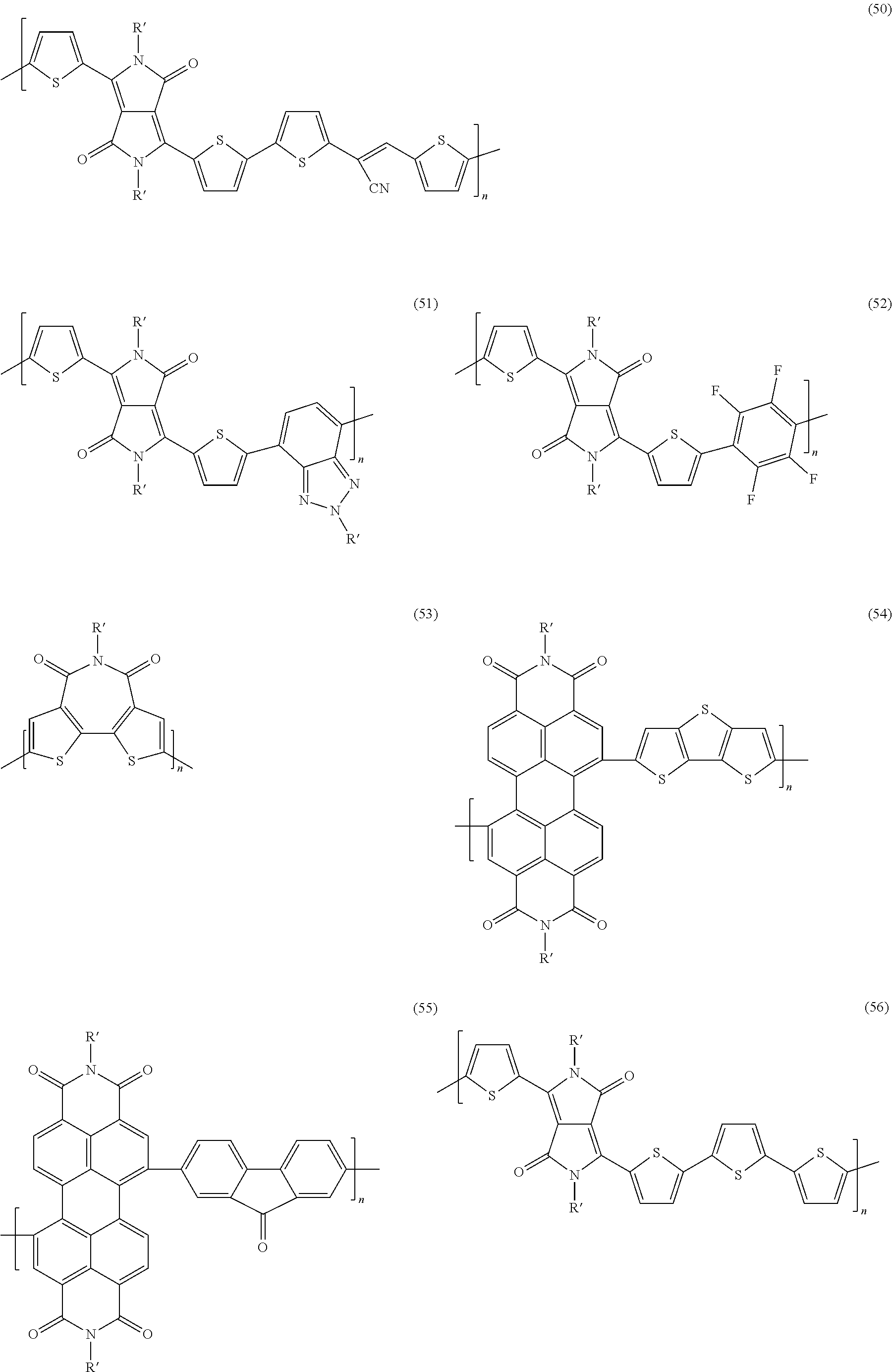

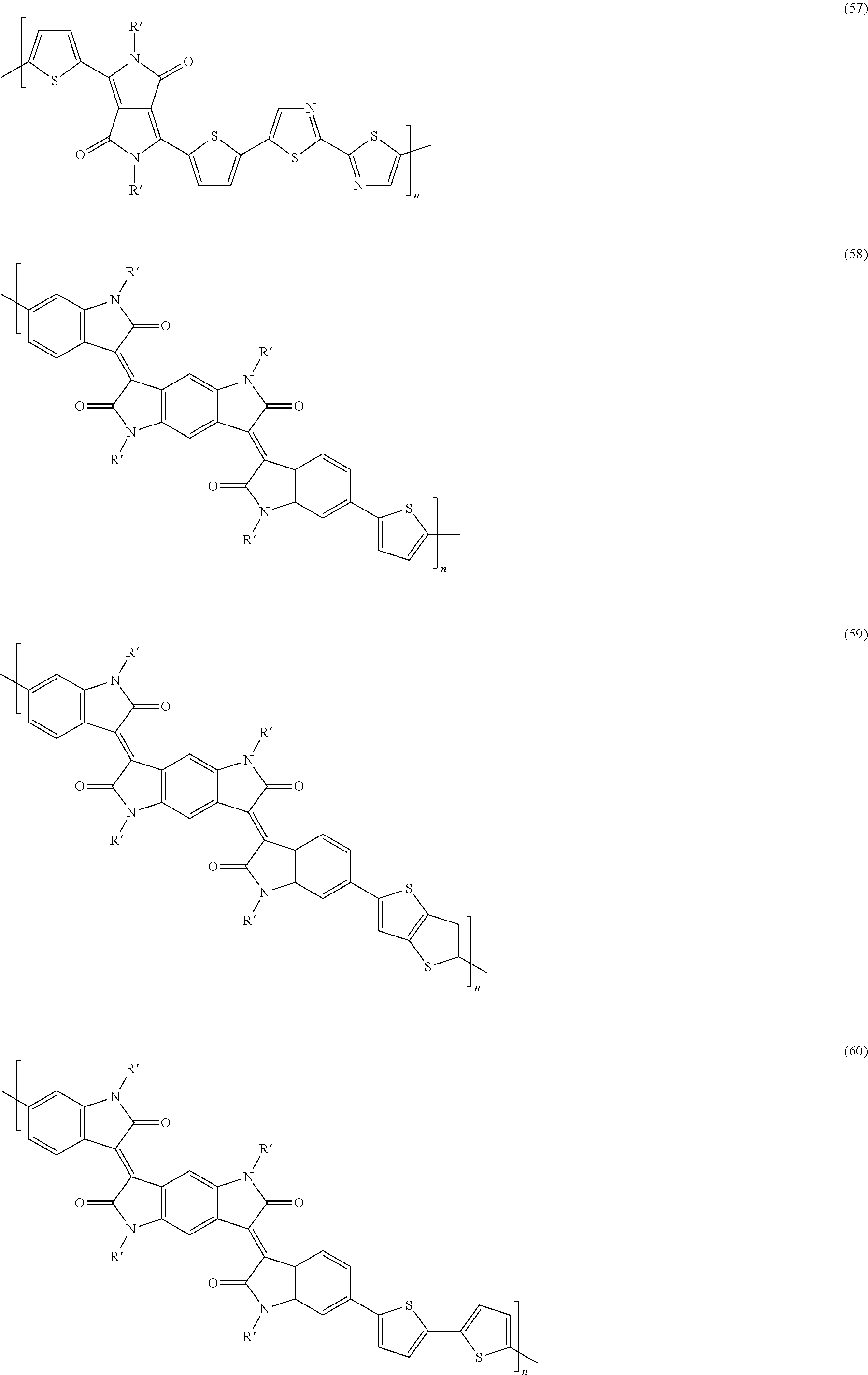

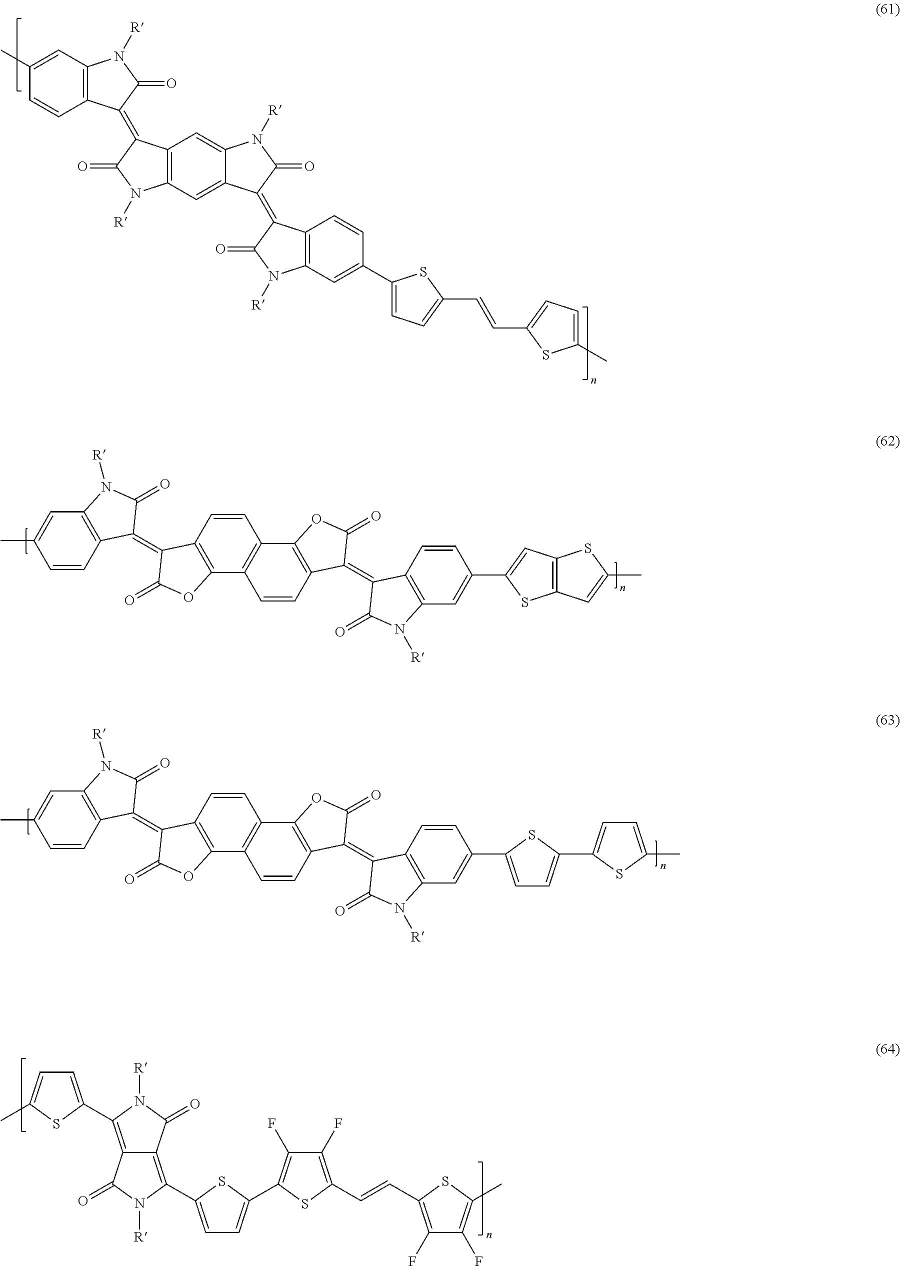

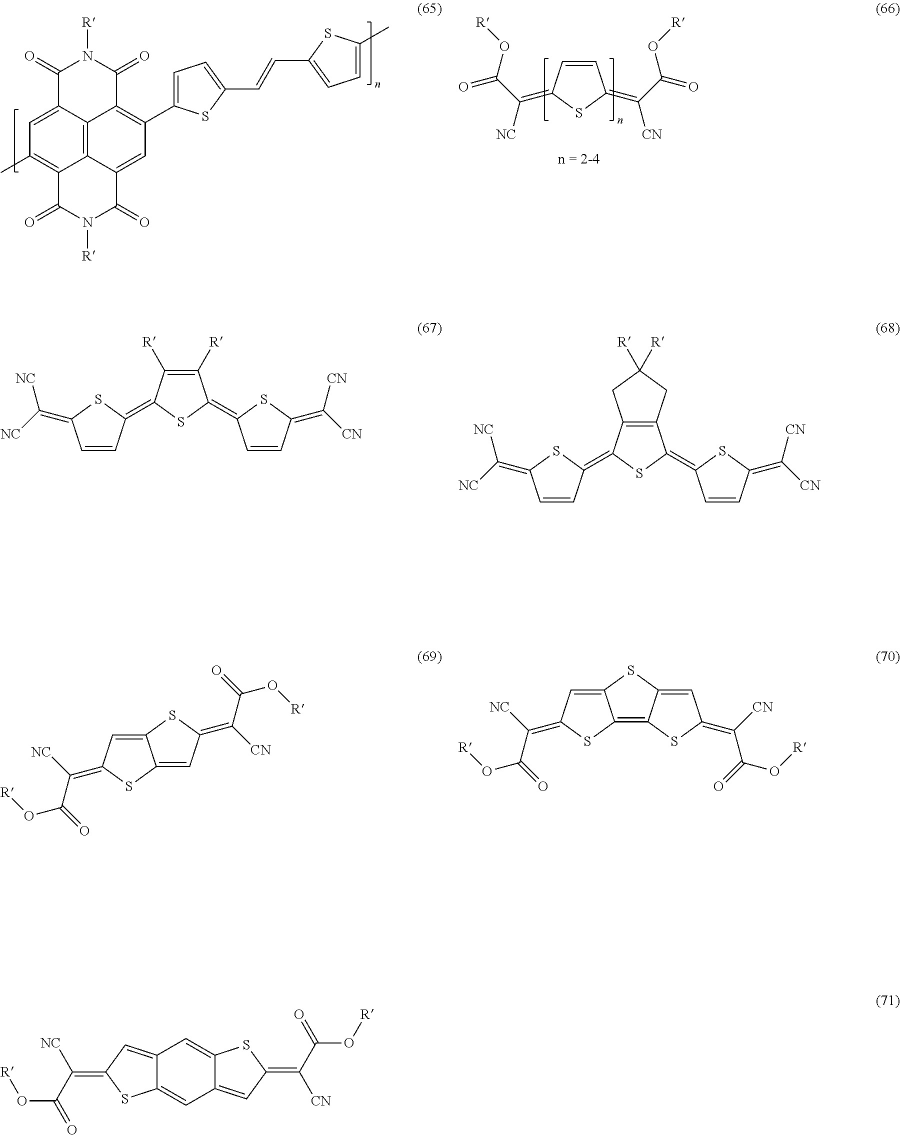

wherein

R′ is independently selected from H, hydroxyl (—OH), hydrocarbon, substituted hydrocarbon, heteroaryl, substituted heteroaryl, heteroalkyl, substituted heteroalkyl, alkoxy, substituted alkoxy, aryloxy, substituted aryloxy, herteroaryloxy, substituted herteroaryloxy, haloalkyl, substituted haloaklyl, —OC(═O)L, SiL₃, —OSiL₃, —N(L)SiL₃, —C(═O)OL, —C(═O)NL₂, imide, cyano (—CN), halogen (F, Cl, Br, or I), —NL₂, —COOH and its salt form, C(O)L, —CN, —NC, —NCO, —NCS, —OCN, —SCN, —SH, —SL, S(═O)L, —SO₃H and its salt form, —SO₂L, —NO₂, —CF₃, —SF₅, or any other suitable group,

a polymer-bound moiety selected from alkylene, substituted alkylene, alkenylene, substituted alkenylene, alkynylene, substituted alkynylene, cycloalkylene, substituted cycloalkylene, arylene, substituted arylene, heteroalkylene, substituted heteroalkylene, heteroarylene, substituted heteroarylene, arylenoxy, substituted arylenoxy, heteroarylenoxy, substituted heteroarylenoxy, biarylene, substituted biarylene, biheteroarylene, substituted biheteroarylene, biarylenoxy, substituted biarylenoxy, biheteroarylenoxy, substituted biheteroarylenoxy, oxy (—O—), —S—, and —N(L)-;

L is H, hydroxyl, hydrocarbon, substituted hydrocarbon, alkoxyl, substituted alkoxy, aryloxy, substituted aryloxy, heteroalkyl, substituted heteroalkyl, heteroaryl, substituted heteroaryl, heteroaryloxy, substituted heteroaryloxy, haloalkyl, substituted haloalkyl, or a group of formula (II) as defined above, etc.; and

n is the number of repeat units and represents an integer from 0 to about 1,000,000.

The terminals of a polymer can be hydrogen, an endcap, or any other suitable group or moiety. The terminals or the internal units of the polymers can be optionally substituted by any suitable group such as hydrogen, optionally substituted hydrocarbon, heteroalkyl, substituted heteroalkyl, heteroaryl, substituted heteroaryl, aryloxy, substituted aryloxy, alkoxy, substituted alkoxy, heteroaryloxy, substituted heteroaryloxy, fluorocarbon, ester, amide, imide, cyano (—CN), halogen (F, Cl, Br, or I), hydroxy (—OH), amino, (—NH₂), a group of formula II as defined above, or any other suitable group, or other π-conjugated polymer blocks.

In some embodiments, the number of repeat units (n) is from about 1 to about 1,000,000. In some embodiments, n is 1 to about 100,000, 1 to about 10,000, 1 to about 5,000, or 1 to about 1000.

In some embodiments, the molecular weight of the repeat unit (n) is from about 100 to about 5000. In some embodiments, the molecular weight of the repeat unit (n) is from about 500 to about 2000, from about 500 to about 1500, from about 500 to about 1000, or from about 1000 to about 2000.

In some embodiments, the molecular weight of the OSC is from about 300 to about 10,000,000. In some embodiments, the molecular weight of the OSC is from about 500 to about 1,000,000. In some embodiments, the molecular weight of the OSC is from about 500 to about 500,000. In some embodiments, the molecular weight of the OSC is from about 500 to about 100,000.

Semiconductor Formulations and Methods

The present disclosure relates to an n-type semiconductor formulation comprising an organic semiconductor (OSC) and an organic phosphorous-containing functional additive (OPA) capable of enhancing the n-type performance of the OSC. The formulation can be prepared by any suitable method know in the art. Furthermore, the semiconductor formulation may be formulated to any desired state, e.g. solid, liquid, etc, based on known methods.

In one embodiment, the organic semiconductor formulation may be prepared by the addition of an OPA to a solution (or dispersion) comprising an OSC. In an alternative embodiment, the organic semiconductor formulation may be prepared by the addition of an OSC to a solution (or dispersion) comprising an OPA. In some embodiments, the method may further comprise isolating the semiconductor formulation by removing the solvent. The organic semiconductor formulation may thereafter be dissolved into a second solvent to form a semiconductor formulation solution. The second solvent may be the same or different from the original solvent.

In some embodiments, the formulation is prepared directly by mixing a functional additive with an organic semiconductor, optionally in the presence of a suitable liquid or solvent. Any suitable liquid or solvent may be used for mixing the functional additive with the organic semiconductor, including, for example, organic solvents and water. The liquid organic solvent may comprise, for example, an alcohol such as methanol, ethanol, propanol, butanol, pentanol, hexanol, heptanol, octanol, a hydrocarbon solvent such as pentane, hexane, cyclohexane, heptane, octane, nonane, decane, undecane, dodecane, tridecane, tetradecane, toluene, xylene, mesitylene, tetrahydrofuran; chlorobenzene; dichlorobenzene; trichlorobenzene; nitrobenzene; cyanobenzene; acetonitrile; alcohols, or derivatives, or combinations thereof, among others.

The weight percentage of solvent in the organic semiconductor formulation may be, for example, from about 0 weight percent to about 99.9 weight percent, from about 20 weight percent to about 99 weight percent or from about 30 weight percent to about 90 weight percent of the total solution weight. The concentration of the functional additive in the organic semiconductor formulation may be, for example, from about 0.05 weight percent to about 99.9 weight percent, from about 0.1 weight percent to about 99 weight percent, from about 0.5 weight percent to about 90 weight percent, or from about 1 weight percent to about 50 weight percent, of the formulation.

One, two, three or more solvents may be used in the preparation of the organic semiconductor formulation. In embodiments where two or more solvents are used, each solvent may be present at any suitable volume ratio or weight ratio such as, for example, from about 99(first solvent):1(second solvent) to about 1(first solvent):99(second solvent).

One, two, three or more OPAs may be used. In embodiments where two or more OPAs are used, each OPA may be present at any suitable weight ratio or molar ratio such as, for example, from about 99(first OPA):1(second OPA) to about 1(first OPA):99(second OPA).

One, two, three or more OSCs may be used. In embodiments where two or more OSCs are used, each OSC may be present at any suitable weight ratio or molar ratio such as, for example, from about 99(first OSC):1(second OSC) to about 1(first OSC):99(second OSC).

In some embodiments, the n-type semiconductor formulation herein may further comprise one or more other materials either conducting, semiconducting, or insolating. Examples of other conducting materials include but are not limited to metal nanoparticles, metal nanowires, metal flakes, graphite, carbon black, and conducting carbon nanotubes. Examples of other conducting materials include but are not limited to TiO₂ (e.g., nanoparticles and nanorods), ZnO (e.g., nanoparticles and nanorods), semiconducting carbon nanotubes, graphene, silicon nanoparticles and nanowires. Examples of other insulating materials include but are not limited to polystyrene, poly(vinyl phenol), poly(vinyl alcohol), poly(vinylpyridine)s, polyimides, polystyrene, polybutadiene, poly(styrene-co-polybutadiene), poly(methacrylate)s, poly(acrylate)s, polyvinylpyrrolidone, cellulose, and epoxy resin. This other material(s) and the OSC may be present at any suitable mass ratio such as for example from about 99 (the other material):1 (OSC) to about 1 (the other material):99 (OSC).

Preparation of the formulation may be carried out at any suitable temperature. In some embodiments, the mixing of the OPA with the OSC is carried out at any suitable temperature to accelerate the mixing, for example, at a temperature in the range from room temperature to 200° C., or from room temperature to 150° C., or from room temperature to 100° C., depending on the boiling point of the solvent and the molecular weight of the OSC. In some embodiments, the mixing may be carried out below room temperature.

In embodiments the solvent in the organic semiconductor formulation prepared above may be optionally removed by any suitable method, such as evaporation or distillation, and a second same or different solvent may be added to dissolve or disperse the organic semiconductor formulation to any desired concentration.

Any suitable solvent can be used for the second solvent, including, for example, organic solvents and/or water. The organic solvents include, for example, hydrocarbon solvents such as pentane, hexane, cyclohexane, heptane, octane, nonane, decane, undecane, dodecane, tridecane, tetradecane, toluene, xylene, mesitylene, and the like; alcohols such as methanol, ethanol, propanol, butanol, pentanol and the like; tetrahydrofuran; chlorobenzene; dichlorobenzene; trichlorobenzene; nitrobenzene; cyanobenzene; acetonitrile; dichloromethane; N,N-dimethylformamide (DMF); and mixtures thereof. One, two, three or more solvents may be used. In embodiments where two or more solvents are used, each solvent may be present at any suitable volume ratio or molar ratio such as for example from about 99(first solvent):1(second solvent) to about 1(first solvent):99(second solvent).

In some embodiments, the method comprises a) mixing an OPA with OSC optionally in the presence of an additional liquid or solvent (the first solvent); and b) optionally removing the first solvent by any suitable method such as evaporation or distillation; and c) optionally adding a second same or different solvent to dissolve or disperse the organic semiconductor formulation to any desirable concentration.

In some embodiments, the present disclosure provides a method for producing an organic semiconductor thin film from an organic semiconductor formulation comprising an OPA and an OSC comprising: a) depositing the formulation on a substrate using a liquid deposition technique; and b) optionally heating the deposited organic semiconductor formulation to form an n-type organic semiconductor layer. In some embodiments, the optionally heating step comprises heating the deposited organic semiconductor formulation at a temperature at or below about 350° C. In some embodiments, the optionally heating step comprises heating the deposited organic semiconductor formulation at a temperature at or below about 200° C.

Electronic Devices

The semiconductor formulation of the present disclosure is suitable for use in a variety of applications, as will be apparent to the skilled person. In some embodiments, the organic semiconductor formulation in the present invention can be used in electronic devices, for example, as a semiconductor or semiconductor layer in an electronic device. The electronic device may be any suitable electronic device, including but not limited to organic thin film transistors (OTFT), organic photovoltaic devices (OPVs), memory devices, sensing devices, organic light emitting devices (OLEDs), radio frequency identification (RFIDs) devices, thermoelectric devices, batteries, among others.

In some embodiments, the electronic device is an OTFT comprising a semiconductor layer comprising an n-type semiconductor formulation as described herein. Exemplification of the semiconductor formulation with reference to an OTFT should not be construed as limiting the scope of the disclosure to OTFT in any way.

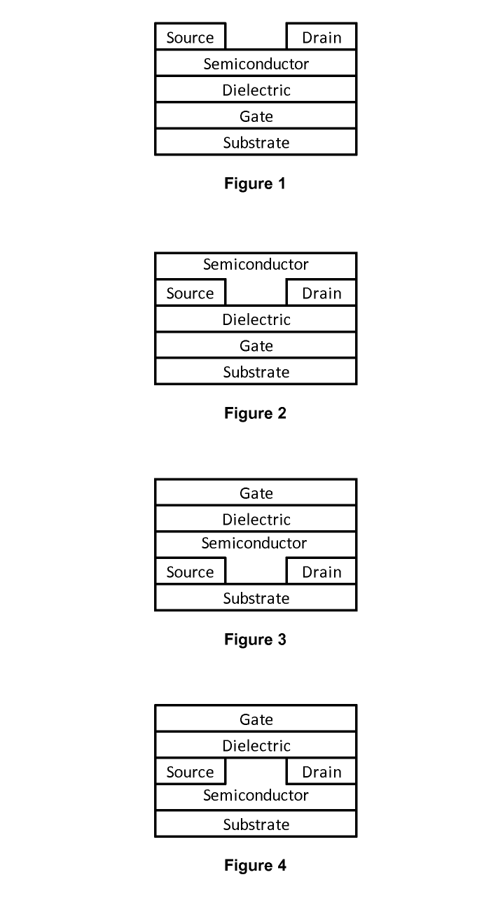

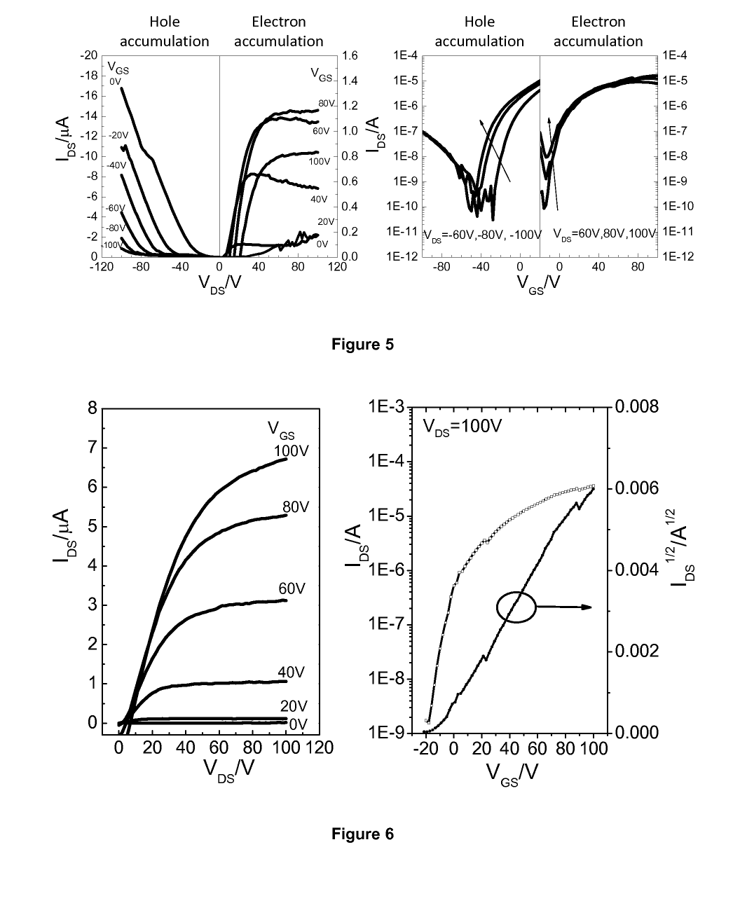

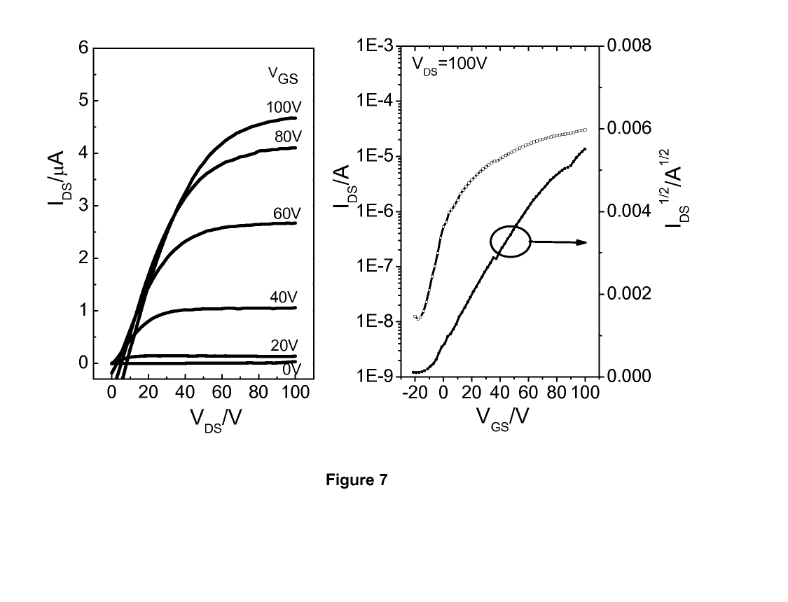

In FIG. 1, there is schematically illustrated a bottom-gate, top-contact OTFT configuration comprised of a substrate, in contact therewith a gate electrode and a layer of a gate dielectric. On top of the gate dielectric there is an organic semiconductor layer. Two conductive contacts, source electrode and drain electrode, are deposited on top of the organic semiconductor layer.

FIG. 2 schematically illustrates a bottom-gate, bottom-contact OTFT configuration comprised of a substrate, a gate electrode, a source electrode and a drain electrode, a gate dielectric layer, and an organic semiconductor layer.

FIG. 3 schematically illustrates a top-gate, bottom-contact OTFT configuration comprised of a substrate, a gate electrode, a source electrode and a drain electrode, a gate dielectric layer, and an organic semiconductor layer.

FIG. 4 schematically illustrates a top-gate, top-contact OTFT configuration comprised of a substrate, a gate electrode, a source electrode and a drain electrode, a gate dielectric layer, and an organic semiconductor layer.

The fabrication of an organic semiconductor thin film from the organic semiconductor formulation can be carried out by any suitable means, for example, by depositing the formulation on a substrate using a liquid deposition technique at any suitable time prior to or subsequent to the formation of other optional layer or layers on the substrate. Thus, in some embodiments, liquid deposition of the organic semiconductor formulation on the substrate can occur either on a substrate or on a substrate already containing layered material, for example, a conducting layer, a semiconducting layer, and/or an insulating layer.

The phrase “liquid deposition technique” refers to, for example, deposition of a composition using a liquid process such as liquid coating or printing, where the liquid is a homogeneous or heterogeneous dispersion of the organic semiconductor and the functional additive in a liquid. The organic semiconductor formulation of this invention may be referred to as an ink when printing is used. Examples of liquid coating processes may include, for example, spin coating, blade coating, rod coating, dip coating, drop casting, and the like. Examples of printing techniques may include, for example, lithography or offset printing, gravure, flexography, screen printing, stencil printing, inkjet printing, stamping (such as microcontact printing), nanoimprinting, and the like. Liquid deposition deposits a layer of the organic semiconductor of this invention having a thickness ranging from about 5 nanometers to about 5 millimeters, preferably from about 10 nanometers to about 1000 micrometers. The deposited organic semiconductor formulation at this stage may or may not exhibit optimal semiconductor performance.

The substrate may be composed of, for example, silicon, glass plate, plastic film or sheet. For structurally flexible devices, plastic substrate, such as, for example, polyester, polycarbonate, polyimide sheets and the like may be used. The thickness of the substrate may be from amount 10 micrometers to about 10 millimeters, from about 50 micrometers to about 2 millimeters, especially for a flexible plastic substrate and from about 0.4 millimeters to about 10 millimeters for a rigid substrate such as glass or silicon.

In some embodiments, heating the deposited organic semiconductor formulation at a temperature of, for example, at or below about 350° C., may improve the desirable characteristics of the organic semiconductor formulation. In some embodiments, lower heating temperatures, e.g. below 200° C., may allow the use of low cost plastic substrates.

The heating can be performed for a time ranging from, for example, 1 second to about 10 hours and from about 10 seconds to 1 hour. The heating can be performed in air or an inert atmosphere, for example, under nitrogen or argon.

In some embodiments, the deposited organic semiconductor formulation without heating or after heating exits n-type semiconductor characteristics, with pronounced electron transport performance and non-appreciable hole transport performance. The “non-appreciable” hole transport performance means the ratio of the hole mobility (μₕ) and the electron mobility (μₑ), μₕ/μₑ, is smaller than 0.01, or smaller than 0.001, or smaller than 0.0001.

In some embodiments, there is provided an organic thin film transistor comprising:

(a) a dielectric layer;

(b) a gate electrode;

(c) a semiconductor layer;

(d) a source electrode;

(e) a drain electrode, and

(f) a substrate,

wherein the semiconductor layer comprises an n-type organic semiconductor formulation of the present disclosure. The dielectric layer, the gate electrode, the semiconductor layer, the source electrode, the drain electrode and the substrate can be in any sequence as long as the gate electrode and the semiconductor layer both contact the insulating dielectric layer, and the source electrode and the drain electrode both contact the semiconductor layer.

In certain embodiments, and with further reference to the present disclosure, the substrate layer may generally be a silicon material inclusive of various appropriate forms of silicon, a metal film or sheet, a glass plate, a plastic film or a sheet, a paper, a fabric, and the like depending on the intended applications. For structurally flexible devices, a metal film or sheet such as, for example, aluminum, a plastic substrate, such as, for example, polyester, polycarbonate, polyimide sheets, and the like, may be selected. The thickness of the substrate may be, for example, from about 10 micrometers to over 10 millimeters with a specific thickness being from about 50 micrometers to about 10 millimeters, especially for a flexible plastic substrate, and from about 0.5 to about 10 millimeters.

The insulating dielectric layer, which can separate the gate electrode from the source and drain electrodes, and in contact with the semiconductor layer, can generally be an inorganic material film, an organic polymer film, or an organic-inorganic composite film. Examples of inorganic materials suitable as the dielectric layer may include silicon oxide, silicon nitride, aluminum oxide, barium titanate, barium zirconate titanate, and the like. Examples of organic polymers for the dielectric layer may include fluorinated polymers such as Cytop (a product of AGC Chemicals), polyesters, polycarbonates, poly(vinyl phenol), poly(vinyl alcohol), polyimides, polystyrene, poly(methacrylate)s, poly(acrylate)s, epoxy resin, and the like. Examples of inorganic-organic composite materials may include spin-on glass such as pMSSQ (polymethylsilsesquioxane), metal oxide nanoparticles dispersed in polymers, such as polyester, polyimide, epoxy resin, and the like. The thickness of the dielectric layer can be, for example, from 1 nanometer to about 5 micrometers with a more specific thickness being about 10 nanometers to about 1000 nanometers.

Situated, for example, between and in contact with the dielectric layer and the source/drain electrodes is the active semiconductor layer comprised of the organic semiconductor formulation of this invention, and wherein the thickness of this layer is generally, for example, about 10 nanometers to about 5 micrometer, or about 40 to about 100 nanometers. This layer can generally be fabricated by solution processes such as spin coating, casting, screen, stamp, or jet printing of a solution of semiconductors.

The gate electrode can be a thin metal film, a conducting polymer film, a conducting film generated from a conducting ink or paste, or the substrate itself (for example heavily doped silicon). Examples of the gate electrode materials may include gold, chromium, indium tin oxide, conducting polymers, such as polystyrene sulfonate-doped poly(3,4-ethylenedioxythiophene) (PSS/PEDOT), a conducting ink/paste comprised of carbon black/graphite or colloidal silver dispersion contained in a polymer binder, such as Electrodag available from Acheson Colloids Company, and silver filled electrically conductive thermoplastic ink, and the like. The gate layer may be prepared by vacuum evaporation, sputtering of metals or conductive metal oxides, coating from conducting polymer solutions or conducting inks, or dispersions by spin coating, casting or printing. The thickness of the gate electrode layer may be, for example, from about 10 nanometers to about 10 micrometers, and a specific thickness is, for example, from about 10 to about 1000 nanometers for metal films, and about 100 nanometers to about 10 micrometers for polymer conductors.

The source and drain electrode layer can be fabricated from materials which provide a low resistance ohmic contact to the semiconductor layer. Typical materials suitable for use as source and drain electrodes may include those of the gate electrode materials such as silver, gold, nickel, aluminum, platinum, and conducting polymers. Typical thickness of this layer may be, for example, from about 40 nanometers to 1 micrometer with the more specific thickness being about 100 to about 400 nanometers. The TFT devices contain a semiconductor channel with a width W and length L. The semiconductor channel width may be, for example, from about 10 micrometers to about 5 millimeters with a specific channel width being about 100 micrometers to 1 millimeter. The semiconductor channel length may be, for example, from 1 micrometer to 1 millimeter with a more specific channel length being from about 5 micrometers to about 100 micrometers.

In embodiments, the channel semiconductor layer in a thin-film transistor is formed by using a method described herein to form a semiconducting layer, the method comprising: mixing a functional additive and an organic semiconductor optionally in a solvent or liquid to form an organic semiconductor formulation dispersion, depositing the organic semiconductor formulation dispersion onto a substrate, and optionally annealing the deposited organic semiconductor formulation to form an n-type semiconductor layer.

### DEFINITIONS

As used herein, the term “hydrocarbon,” used alone or in combination, refers to a linear, branched or cyclic organic moiety comprising carbon and hydrogen, for example, alkyl, alkene, alkyne, and aryl, which may each be optionally substituted. A hydrocarbon may, for example, comprise about 1 to about 60 carbons, about 1 to about 40 carbons, about 1 about 30 carbons, about 1 about 20 carbons, about 1 to about 10 carbons, about 1 to about 9 carbons, about 1 to about 8 carbons, about 1 to about 6 carbons, about 1 to about 4 carbons, or about 1 to about 3 carbons. In some embodiments, hydrocarbon comprises 10 carbons, 9 carbons, 8 carbons, 7 carbons, 6 carbons, 5 carbons, 4 carbons, 3 carbons, 2 carbons, or 1 carbon.

The term “alkyl”, used alone or in combination, means a straight or branched hydrocarbon group as defined above. In some embodiments, alkyl has about 1 to about 60 carbons, about 1 to about 40 carbons, about 1 about 30 carbons, about 1 to about 20, 1 to about 10, 1 to about 8 or 1 to about 6 carbons. Examples of branched or unbranched C₁-C₈ alkyl groups include, for example, methyl, ethyl, propyl, isopropyl, butyl, isobutyl, tert-butyl, the isomeric pentyls, the isomeric hexyls, the isomeric heptyls, and the isomeric octyls.

As used herein, “heteroalkyl” refers to a linear, branched or cyclic alkyl group wherein one or more carbons is replaced with a heteroatom, such as S, O, P and N. Exemplary heteroalkyls include alkyl ethers, secondary and tertiary alkyl amines, amides, alkyl sulfides, and the like.

The term “alkoxy”, used alone or in combination, means the group —O-alkyl, wherein the alkyl group is as defined above. Examples include, for example, methoxy, ethoxy, n-propyloxy, and iso-propyloxy.

The term “cycloalkyl”, used alone or in combination, means a cyclic alkyl group having at least 3 carbon atoms, wherein alkyl is as defined above.

The term “alkenyl”, used alone or in combination, means a straight or branched chain hydrocarbon having at least 2 carbon atoms, which contains at least one carbon-carbon double bond. In some embodiments, alkenyl has about 2 to about 60 carbons, about 2 to about 40 carbons, about 2 about 30 carbons, about 2 to about 8 carbons. In some embodiments, alkenyl has 2 to 8 carbon atoms. Examples of alkenyl groups include, for example, vinyl, allyl, isopropenyl, pentenyl, hexenyl, heptenyl, 1-propenyl, 2-butenyl and 2-ethyl-2-butenyl.

“Haloalkyl” means alkyl as defined herein in which one or more hydrogen has been replaced with same or different halogen. Exemplary haloalkyls include —CH₂Cl, —CH₂CF₃, —CH₂CCl₃, perfluoroalkyl (e.g., —CF₃), and the like.

The term “alkynyl”, used alone or in combination, means a straight or branched chain hydrocarbon having at least 2 carbon atoms, which contains at least one carbon-carbon triple bond. In some embodiments, alkynyl has about 2 to about 60 carbons, about 2 to about 40 carbons, about 2 about 30 carbons, about 2 to about 8 carbons. Examples of alkynyl groups include, for example, ethynyl, 1-propynyl, 1- and 2-butynyl, and 1-methyl-2-butynyl.

The term “alkenylene” means a divalent form of an alkenyl group, as defined above.

The term “alkynylene” means a divalent form of an alkynyl group, as defined above.

The term “cycloalkylene” means a divalent form of a cycloalkyl group, as defined above.

The term “alkoxyalkyl” means a moiety of the formula —R′—R″, where R′ is alkylene and R″ is alkoxy as defined herein. Exemplary alkoxyalkyl groups include, by way of example, 2-methoxyethyl, 3-methoxypropyl, l-methyl-2-methoxyethyl, I-(2-methoxyethyl)-3-methoxypropyl, and I-(2-methoxyethyl)-3-methoxypropyl.

The term “alkylcarbonyl” means a moiety of the formula —C(O)—R, where R is alkyl as defined herein.

The term “alkoxycarbonyl” means a moiety of formula —C(O)—R wherein R is alkoxy as defined herein.

“Alkylsulfanyl” means a moiety of the formula —S—R wherein R is alkyl as defined herein.

“Alkylsulfinyl” means a moiety of the formula —SO—R wherein R is alkyl as defined herein.

“Alkylsulfonyl” means a moiety of the formula —SO₂—R′ where R′ is alkyl as defined herein.

“Aminosulfonyl” means a moiety of the formula —SO₂—R′ where R′ is amino as defined herein.

“Hydroxyalkyl” refers to an alkyl moiety as defined herein that is substituted with one or more, preferably one, two or three hydroxy groups, provided that the same carbon atom does not carry more than one hydroxy group.

The term “aryl”, used alone or in combination, means an aromatic carbocyclic moiety of up to 60 carbon atoms, which may be a single ring (monocyclic) or multiple rings fused together (e.g., bicyclic or tricyclic fused ring systems). In some embodiments, aryl has up to 60 carbon atoms, up to 40 carbon atoms, up 20 carbon atoms, up to 12 carbon atoms, up to 10 carbon atoms, up to 9 carbon atoms, or up to 6 carbon atoms. Any suitable ring position of the aryl moiety may be covalently linked to a defined chemical structure. Examples of aryl moieties having up to 20 carbons include, but are not limited to phenyl, napthyl (e.g. 1-naphthyl, 2-naphthyl), dihydronaphthyl, tetrahydronaphthyl, anthryl, phenanthryl, fluorenyl, indanyl, acenaphthenyl, acenaphthylenyl, and the like.

The term “heteroaryl”, used alone or in combination, means a radical derived from an aromatic carbocyclic moiety of up to 60 ring atoms, comprising carbon atom ring atoms and one or more heteroatom ring atoms. Each heteroatom is independently selected from nitrogen, which can be oxidized (e.g., N(O)) or quaternized; oxygen; and sulfur, including sulfoxide and sulfone. In some embodiments, heteroaryl has up to 40 ring atoms, up to 20 ring atoms, up to 12 ring atoms, up to 10 ring atoms, up to 9 ring atoms, up to 6 ring atoms or up to 5 ring atoms. The heteroaryl group can be a monocyclic or polycyclic heteroaromatic ring system including but not limited to condensed heterocyclic aromatic rings, and condensed carbocyclic and heterocyclic aromatic rings. The point of attachment of a heteroaryl group to another group may be at either a carbon atom or a heteroatom of the heteroaryl group. Non-limiting representative heteroaryl groups include pyridyl, 1-oxo-pyridyl, furanyl, benzo[1,3]dioxolyl, benzo[1,4]dioxinyl, thienyl, pyrrolyl, oxazolyl, imidazolyl, thiazolyl, a isoxazolyl, quinolinyl, pyrazolyl, isothiazolyl, pyridazinyl, pyrimidinyl, pyrazinyl, a triazinyl, triazolyl, thiadiazolyl, isoquinolinyl, indazolyl, benzoxazolyl, benzofuryl, indolizinyl, imidazopyridyl, tetrazolyl, benzimidazolyl, benzothiazolyl, benzothiadiazolyl, benzoxadiazolyl, indolyl, tetrahydroindolyl, azaindolyl, imidazopyridyl, quinazolinyl, purinyl, pyrrolo[2,3]pyrimidinyl, pyrazolo[3,4]pyrimidinyl, imidazo[1,2-a]pyridyl, benzothienyl, isobenzofuranyl, isoquinolyl, pteridinyl, quinolyl, etc.

Unless otherwise specified, the term “substituted” that one or more hydrogen atoms have been replaced with a substituent. A skilled person will be able to select a suitable type, number and position of substituents for a desired compound, function and application. Substituents include, but are not limited to, groups selected from alkyl, alkenyl, alkynyl, alkoxy, acyloxy, alkoxyalkyl, alkylamino, alkanoyl, alkylcarbonyl, alkylsulfonyl, alkylsulfinyl, alkylsulfonyloxy, alkylsulfanyl, alkylsulfonamido, alkoxycarbonyl, alkylenedioxy, amino, amido, aminosulfonyl, aralkyl, aryloxy, alkylthio, aryl, arylthio, benzyloxy, carboxy, carbonyl, carbamoyl, cycloalkyl, cycloalkylalkyl, cycloalkoxy, cycloalkylalkoxy, cyano, ester, hydrogen, halo, haloalkyl (e.g. fluorocarbon, trifluoromethyl), haloalkoxy (e.g. trifluoromethoxy), heteroaryl, heteroalkyl, hydroxy, hydroxyalkyl, mercapto, nitro, thiol, thioyl, among others. Substituents themselves can also be optionally substituted.

In some embodiments, an aryl or heteroaryl R or R′ group is optionally substituted with one, two or three substituents independently selected from alkyl, halo, haloalkyl, alkoxy, cyano, amino, amido, nitro, thio, aminosulfonyl, alkylsulfonyl, alkylsulfanyl, alkoxycarbonyl, alkylcarbonyl, hydroxy, hydroxyalkyl, and alkylenedioxy. cycloalkyl, carboxy, alkoxycarbonyl, hydroxy, haloalklyl, haloalkoxy, among others.

In some embodiments, an aryl or heteroaryl R or R′ group is substituted with one, two or three substituents independently selected from methyl, ethyl, fluoro, chloro, bromo, trifluoromethyl, methoxy, ethoxy, amino, aminosulfonyl, methanesulfonyl, methylsulfanyl, acetyl, hydroxymethyl, hydroxy, —C(O)OEt, C(O)O-tert-butyl, and cyano.

The term “aryloxy”, used alone or in combination, means the group —O-aryl, wherein the aryl group is as defined above. The term “heteroaryloxy”, used alone or in combination, means the group —O-heteroaryl, wherein the heteroaryl group is as defined above.

The term “arylene” means a divalent form of an aryl, as defined above, such as ortho-phenylene, meta-phenylene, para-phenylene, and the naphthylenes. The term “heteroarylene” means a divalent form of a heteroaryl radical, as defined above.

The term “aryloxy”, used alone or in combination, means the group —O-arylene, wherein the arylene group is as defined above. The term “heteroaryloxy”, used alone or in combination, means the group —O-heteroarylene, wherein the heteroarylene group is as defined above.

The term “biarylene” means a bidentate group comprising two aryl groups attached together by a single bond, and having a point of attachment on each aryl group. The term “heterobiarylene” means a bidentate group comprising two heteroaryl groups attached together by a single bond, and having a point of attachment on each heteroaryl group.

The term “biaryloxy” means a bidentate group comprising two aryloxy groups attached together by a single bond, and having a point of attachment on the oxygen atom of each aryloxy group. The term “heterobiaryloxy” means a bidentate group comprising two heteroaryloxy groups attached together by a single bond, and having a point of attachment on the oxygen atom of each heteroaryloxy group.

As used herein, the term “amino” means —NRR′ where R and R′ are independently hydrogen or alkyl as defined herein.

As used herein, the term “polymer” will be understood to mean a molecule that encompasses a backbone of one or more distinct types of repeat units (the smallest constitutional unit of the molecule) and is inclusive of the commonly known terms “oligomer” (e.g. 10 repeat units or less), “copolymer”, “block copolymer,” “homopolymer” and the like.

As used herein, the terms “repeat unit” and “monomer” are used interchangeably and will be understood to mean the constitutional repeating unit (CRU), which is the smallest constitutional unit, the repetition of which constitutes a regular macromolecule, a regular oligomer molecule, a regular block or a regular chain.

As used herein, a “terminal group” will be understood to mean a group that terminates a polymer backbone. Such terminal groups may include endcap groups or reactive groups that are attached to a monomer forming the polymer backbone, which did not participate in the polymerisation reaction. As used herein, the term “endcap group” will be understood to mean a group that is attached to, or replacing, a terminal group of the polymer backbone. The end group can, for example, be H, optionally substituted hydrocarbon, heteroaryl, substituted heteroaryl, alkoxy, substituted alkoxy, fluorocarbon, ester, amide, imide, cyano, halogen (F, Cl, Br, or I), hydroxy, amino, or a different polymer block, or any other suitable group. Exemplary endcap groups include, but are not limited to, H, alkyl having from 1 to 60 carbon atoms (e.g. from 1 to 40, 1 to 20, or 1 to 10 carbons), optionally substituted C₆-C₁₂ aryl (e.g. phenyl) or C₂-C₁₀ heteroaryl.

As used herein, the terms “donor” or “donating” and “acceptor” or “accepting” will be understood to mean an electron donor and electron acceptor, respectively. “Electron donor” will be understood to mean a chemical entity that donates electrons to another compound or another group of atoms of a compound. “Electron acceptor” will be understood to mean a chemical entity that accepts electrons transferred to it from another compound or another group of atoms of a compound.

As used herein, the “electron-donating” characteristic of the OPA refers to the ability of donating (or transferring) electrons to the OSC in the formulation in the operational state only or in both the non-operational and the operational states of an electronic device. In some cases, such as in an OTFT device, it is preferred that the donation or transfer of electrons from OPA to the OSC does not occur (or negligibly occurs) in the non-operational state (off-state) and when electrons are injected to the channel (in the n-channel operation state), but occurs when holes are injected to the channel (in the p-channel operational state). In some other cases, such as in a thermoelectric device or a battery, it is preferred that the donation or transfer of electrons from OPA to the OSC occurs in both the non-operational state (off-state) and in the operational state. Additionally, the “electron-donating” characteristic of the OPA refers to the ability of donating (or transferring) electrons to the electron traps in the semiconductor layer or component comprising the n-type semiconductor formulation comprising an OSC and an OPA. An “electron trap” refers to a chemical or structural defect present in the OSC molecule, the grain boundary of the OSC, or a chemical impurity, which can attract or capture an electron injected to the semiconductor layer or component, leading to a reduced electron mobility of the semiconductor. The “electron-donating” characteristic of the OPA herein further refers to the ability of donating (or transferring) electrons to the semiconductor layer or component to increase the electron concentration (resulting in a raised Fermi level). The increased electron concentration would inhibit hole injection and trap injected holes, thereby suppressing hole transport.

As used herein, the term “n-type” or “n-type semiconductor” will be understood to mean a semiconductor in which the conduction electron density is in excess of the mobile hole density, and the term “p-type” or “p-type semiconductor” will be understood to mean a semiconductor in which mobile hole density is in excess of the conduction electron density. As used herein, the term “ambipolar” or “ambipolar semiconductor” is used interchangeably with “bipolar” or “bipolar semiconductor,” respectively, and will be understood to mean a semiconductor that facilitates transport of both holes and electrons.

As used herein, the term “enhancing n-type performance” or “enhanced n-type performance” refers to one or more of reduced hole transport performance (e.g. toward unipolar electron transport), increased electron transport performance and increased current on-to-off ratio. In some cases, the OPA can significantly reduce or effectively eliminate hole transport performance of an OSC.

As used herein, the term “substantially n-type” will be understood to mean a semiconductor, semiconductor formulation or semiconductor layer that exhibits little to no hole transport activity. The expression “little to no hole transport activity” or “non-appreciable” hole transport performance means that the ratio of hole mobility (μₕ) to electron mobility (μₑ), μₕ/μₑ, is smaller than about 0.01, or more preferably smaller than about 0.001, or more preferably smaller than about 0.0001.

As used herein, the term “solution” is intended to encompass homogeneous solutions as well as dispersions. Similarly, the term “solvent” is intended to encompass a solvent that completely dissolves a solute as well as a dispersing medium.

As used herein, the term “mixing” is intended to encompass any suitable means of combining two or more elements, including mixing, admixing, combining, contacting, blending, and the like.

As used herein, the term “conjugated” will be understood to mean a compound that contains C atoms with sp²-hybridisation (or optionally also sp-hybridization), and wherein these C atoms may also be replaced by hetero atoms. In the simplest case this is, for example, a compound with alternating C—C single and double (or triple) bonds, but is also inclusive of compounds with aromatic units like, for example, aryl and heteroaryl as defined above.

As used herein, unless stated otherwise, molecular weight of polymers is given as the number average molecular weight Mₙ or weight average molecular weight M_{w}, which is determined by gel permeation chromatography (GPC). The molecular weight distribution (“MWD”), which may also be referred to as polydispersity index (“PDI”), of a polymer is defined as the ratio M_{w}/Mₙ. The degree of polymerization, also referred to as total number of repeat units, m (or n), will be understood to mean the number average degree of polymerization given as m (or n)=Mₙ/Mᵤ, wherein Mₙ is the number average molecular weight and Mᵤ is the molecular weight of the single repeat unit.

Room temperature refers to a temperature ranging for example from about 20 to about 25° C.

Unless the context clearly indicates otherwise, as used herein plural forms of the terms herein are to be construed as including the singular form and vice versa.

Throughout the description and claims of this specification, the words “comprise” and “contain” and variations of the words, for example “comprising” and “comprises”, mean “including but not limited to”, and are not intended to (and do not) exclude other components.

Above and below, unless stated otherwise percentages are percent by weight and temperatures are given in degrees Celsius.

All documents cited herein are incorporated by reference.

The above-described embodiments are intended to be examples only. Alterations, modifications and variations can be effected to the particular embodiments by those of skill in the art. The scope of the claims should not be limited by the particular embodiments set forth herein, but should be construed in a manner consistent with the specification as a whole.

The invention will now be described in detail with respect to specific representative embodiments thereof, it being understood that these examples are intended to be illustrative only and the invention is not intended to be limited to the materials, conditions, or process parameters recited herein.

### EXAMPLES

### Example 1

### Preparation of Organic Semiconductor Formulations Using Polymer (3) and an OPA

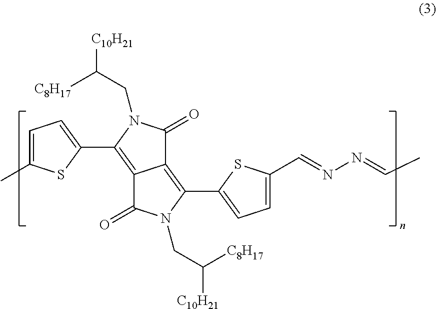

A mixture of Polymer (3) (the number average molecular weight, Mₙ=105 kDa; polydispersity index, PDI=4.3) (10 mg), an OPA with a varied amount, and chlorobenzene (CB) (2.5 mL) is stirred in a vial at 50° C. until all solid is dissolved. After cooling down to room temperature, the solution is filtered using a 0.2 μm Teflon syringe filter to obtain an organic semiconductor formulation.

### Example 2

### Preparation of Organic Semiconductor Formulations Using Polymer (30) and an OPA

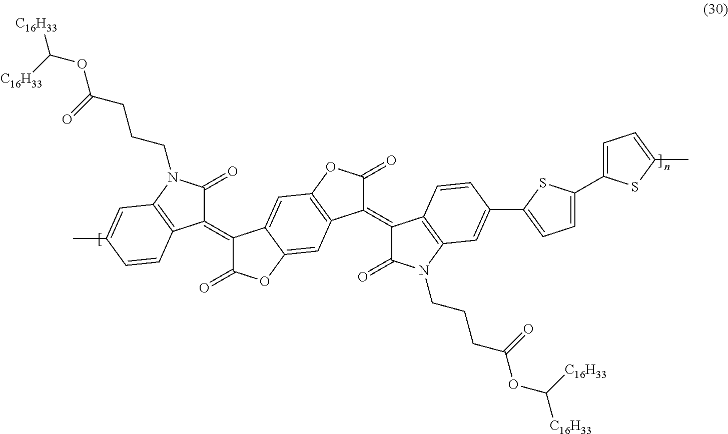

A mixture of Polymer (30) (the number average molecular weight, Mₙ=40 kDa; polydispersity index, PDI=3.4) (10 mg), an OPA with a varied amount, and chlorobenzene (CB) (2.5 mL) is stirred in a vial at 50° C. until all solid is dissolved. After cooling down to room temperature, the solution is filtered using a 0.2 μm Teflon syringe filter to obtain an organic semiconductor formulation.

### Example 3

### Preparation of Organic Semiconductor Formulations Using Polymer (62) and an OPA

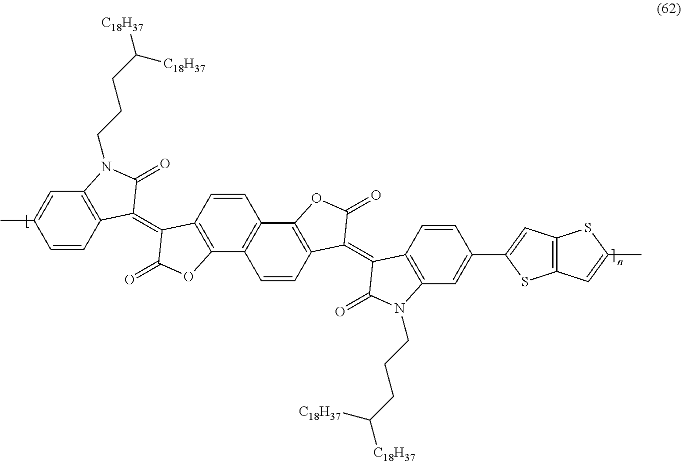

A mixture of Polymer (62) (the number average molecular weight, Mₙ=28 kDa; polydispersity index, PDI=4.9) (10 mg), an OPA with a varied amount, and chlorobenzene (CB) (2.5 mL) is stirred in a vial at 50° C. until all solid is dissolved. After cooling down to room temperature, the solution is filtered using a 0.2 μm Teflon syringe filter to obtain an organic semiconductor formulation.

### Example 4

### Device Fabrication and Evaluation Using Formulations Prepared in Examples 1 to 3 as Channel Materials for OTFT

A bottom-gate bottom-contact (BGBC) OTFT device configuration is selected (FIG. 2), using a silicon substrate with a 300 nm thick SiO₂ top layer. Source and drain electrodes are deposited on the SiO₂ surface by a conventional photolithography technique. Prior to use, the substrate is cleaned by air plasma, washed with acetone, isopropanol (IPA) and deionized (DI) water. An organic semiconductor formulation from Examples 1 to 3 prepared as above is spin coated on the substrate, followed by annealing on a hotplate at 50° C. for 15 min in nitrogen. The devices were characterized in the same glove box with an Agilent B2912A Semiconductor Analyzer. The hole and electron mobilities are calculated in the saturation regions according to the following equation:

I_{SD}=Cᵢμ(W/2L)(V_{G}−V_{T})² (1)

where I_{D} is the drain current, W and L are the device channel width and length, Cᵢ is the gate dielectric layer capacitance per unit area (˜11.6 nF cm⁻²), p is the carries mobility, V_{G} and V_{T} are gate voltage and threshold voltage.

The performance parameters of OTFTs based on the organic semiconductor formulations prepared in Examples 1 to 3 are summarized in Table 1.

TABLE 1
Summary of device performance of OTFTs using polymer
semiconductor formulations.

| | Formulation | T_{Ann.}^{b)} | μ_{e,ave}^{c)} | μ_{h,ave}^{d)} | |
|---|---|---|---|---|---|
| Example | OSC + % OPA^{a)} | [° C.] | [cm²V⁻¹s⁻¹] | [cm²V⁻¹s⁻¹] | Iₒₙ/I_{off}^{e)} |
| 1 | (3) | 50 | 0.022 | 0.0042 | 10² |
| | (3) | 100 | 0.071 | 0.052 | 10² |
| | (3) + 5% PPh₃ | 50 | 0.020 | None | 10² |
| | (3) + 5% PPh₃ | 100 | 0.12 | ~10⁻⁴ | 10³ |
| | (3) + 2% P(o-tolyl)₃ | 50 | 0.018 | None | 10⁴ |
| | (3) + 2% P(o-tolyl)₃ | 100 | 0.027 | 0.0058 | 10³ |
| | (3) + 2% P(o-MeOPh)₃ | 50 | 0.018 | None | 10³-10⁴ |
| | (3) + 2% P(o-MeOPh)₃ | 100 | 0.020 | ~10⁻⁵ | 10³-10⁴ |
| | (3) + 2% (R)-BINAP | 50 | 0.03 | None | 10⁴ |
| | (3) + 2% (R)-BINAP | 100 | 0.044 | None | 10⁴ |
| 2 | (30) | 100 | 0.24 | 0.096 | 10-10² |
| | (30) + 2% (R)-BINAP | 50 | 0.061 | None | 10⁵ |
| | (30) + 2% (R)-BINAP | 100 | 0.086 | None | 10⁵ |
| | (30) + 10% (R)-BINAP | 50 | 0.10 | None | 10⁵ |
| | (30) + 10% (R)-BINAP | 100 | 0.11 | None | 10⁵ |
| 3 | (62) | 50 | 0.043 | 0.036 | 10-10² |
| | (62) + 2% (R)-BINAP | 50 | 0.036 | None | 10⁵ |
| | (62) + 2% (R)-BINAP | 100 | 0.044 | None | 10⁵ |
| | (62) + 10% (R)-BINAP | 50 | 0.025 | None | 10⁵ |
| | (62) + 10% (R)-BINAP | 100 | 0.039 | None | 10⁵ |

^{a)}The weight percentage of the organic phosphorous-containing functional additive (OPA) over the weight of the organic semiconductor (OSC), where PPh₃ is triphenylphosphine, (R)-BINAP is (R)-(+)-(1,1′-binaphthalene-2,2′-diy)bis(diphenylphosphine), P(o-tolyl)₃ is tri(o-tolyl)phosphine, and P(o-MeOPh)₃ is tri(o-methoxyphenyl)phosphine;
^{b)}The temperature at which the semiconductor layer was thermally annealed;
^{c)}the average electron mobility from at least five devices;
^{d)}the average hole mobility from at least five devices;
^{e)}on-to-off current ratio.

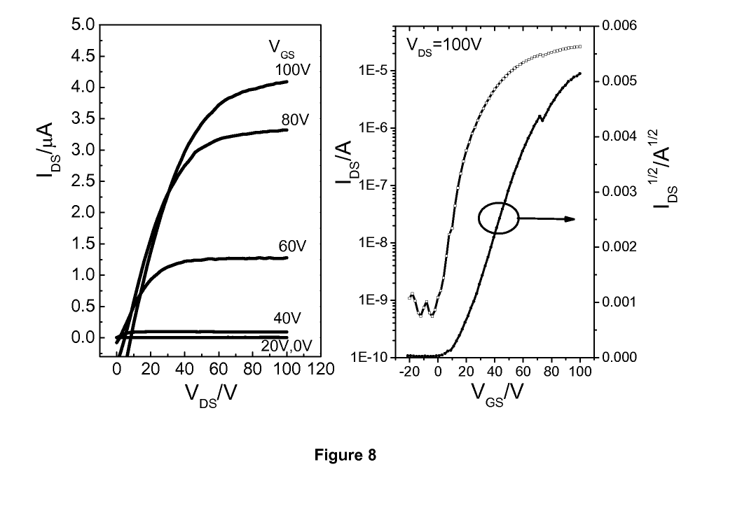

Output and transfer curves of some of the devices are shown in FIG. 8.

While the present invention has been described with reference to the specific embodiments thereof, it should be understood by those skilled in the art that various changes may be made and equivalents may be substituted without departing from the true spirit and scope of the invention. In addition, many modifications may be made to adapt a particular situation, material, composition of matter, process, process step or steps, to the objective spirit and scope of the present invention. All such modifications are intended to be within the scope of the claims appended hereto.

What is claimed is:

1. An organic semiconductor formulation comprising:
an organic semiconductor (OSC); and
an organic phosphorous-containing additive (OPA) capable of enhancing n-type performance of the organic semiconductor.

2. The organic semiconductor formulation of claim 1, wherein the OPA comprises an electron-donating compound or moiety of the general formula PR₃, wherein each R is, independently, hydrogen, hydrocarbon, substituted hydrocarbon, heteroaryl, substituted heteroaryl, alkoxy, substituted alkoxy, aryloxy, substituted aryloxy, herteroaryloxy, substituted herteroaryloxy, haloalkyl, substituted haloaklyl, heteroalkyl, substituted heteroalkyl, hydroxyl, and cyano, and wherein PR₃ may optionally be a moiety incorporated in the backbone of a polymer or a side chain of a polymer.

3. The organic semiconductor formulation of claim 2, wherein at least two R groups are, independently, aryl, substituted aryl, heteroaryl, substituted heteroaryl, aryloxy, substituted aryloxy, herteroaryloxy or substituted herteroaryloxy.

4. The organic semiconductor formulation of claim 1, wherein the OPA comprises one or more organic phosphorous-containing compounds or moieties having the general formula (I): 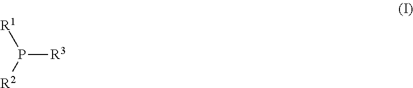
wherein:
R¹, R², and R³ are, independently, any suitable group, e.g., a group selected from H, hydroxyl (—OH), hydrocarbon, substituted hydrocarbon, heteroaryl, substituted heteroaryl, heteroalkyl, substituted heteroalkyl, alkoxy, substituted alkoxy, aryloxy, substituted aryloxy, herteroaryloxy, substituted herteroaryloxy, haloalkyl, substituted haloaklyl, —OC(═O)L, SiL₃, —OSiL₃, —N(L)SiL₃, —C(═O)OL, —C(═O)NL₂, cyano (—CN), halogen (F, Cl, Br, or I), —NL₂, —COOH and its salt form, C(O)L, —CN, —NC, —NCO, —NCS, —OCN, —SCN, —SH, —SL, —S(═O)L, —CF₃, or
a group of formula (II) 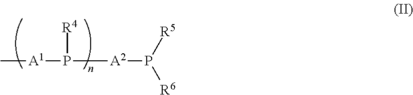
wherein R⁴, R⁵ and R⁶ are as defined above for R¹, R², and R³, or
a polymer-bound moiety selected from alkylene, substituted alkylene, alkenylene, substituted alkenylene, alkynylene, substituted alkynylene, cycloalkylene, substituted cycloalkylene, arylene, substituted arylene, heteroalkylene, substituted heteroalkylene, heteroarylene, substituted heteroarylene, arylenoxy, substituted arylenoxy, heteroarylenoxy, substituted heteroarylenoxy, biarylene, substituted biarylene, biheteroarylene, substituted biheteroarylene, biarylenoxy, substituted biarylenoxy, biheteroarylenoxy, substituted biheteroarylenoxy, oxy (—O—), —S—, and —N(L)-;
A¹ and A² are independently alkylene, substituted alkylene, alkenylene, substituted alkenylene, alkynylene, substituted alkynylene, cycloalkylene, substituted cycloalkylene, arylene, substituted arylene, heteroalkylene, substituted heteroalkylene, heteroarylene, substituted heteroarylene, heteroarylenoxy, substituted heteroarylenoxy, biarylene, substituted biarylene, biheteroarylene, substituted biheteroarylene, biarylenoxy, substituted biarylenoxy, biheteroarylenoxy, or substituted biheteroarylenoxy, oxy (—O—), —S—, and —N(L)-;
L is H, hydroxyl, hydrocarbon, substituted hydrocarbon, alkoxyl, substituted alkoxy, aryloxy, substituted aryloxy, heteroalkyl, substituted heteroalkyl, heteroaryl, substituted heteroaryl, heteroaryloxy, substituted heteroaryloxy, haloalkyl, substituted haloalkyl etc; and
n is an integer from 0 to about 1,000,000.

5. The organic semiconductor formulation of claim 1, wherein the OPA comprises one or more organic phosphorous-containing compounds or moieties having the general formula (I): 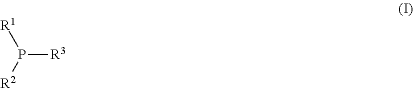
wherein:
R¹ is aryl, substituted aryl, aryloxy, substituted aryloxy, heteroaryl, substituted heteroaryl, or a polymer-bound moiety selected from a polymer-bound oxy, alkyl, substituted alkyl, heteroalkyl, substituted heteroalkyl, alkylene, substituted alkylene, alkenylene, substituted alkenylene, alkynylene, substituted alkynylene, alkoxy, substituted alkoxy, arylene, substituted arylene, arylenoxy, substituted arylenoxy, heteroarylene, substituted heteroarylene, heteroarylenoxy, or substituted heteroarylenoxy;
R² is aryl, substituted aryl, aryloxy, substituted aryloxy, heteroaryl, or substituted heteroaryl;
R³ is any suitable substituent, for example, H, aryl, substituted aryl, heteroaryl, substituted heteroaryl, alkyl, substituted alkyl, alkoxy, substituted alkoxy, aryloxy or substituted aryloxy; or
R³ is a group of formula (II): 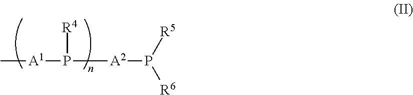
wherein R⁴, R⁵ and R⁶ are independently aryl, substituted aryl, aryloxy, substituted aryloxy, heteroaryl or substituted heteroaryl; and
A¹ and A² are independently alkylene, substituted alkylene, alkenylene, substituted alkenylene, alkynylene, substituted alkynylene, cycloalkylene, substituted cycloalkylene, arylene, substituted arylene, heteroalkylene, substituted heteroalkylene, heteroarylene, substituted heteroarylene, biarylene, substituted biarylene, biheteroarylene, substituted biheteroarylene, biarylenoxy, substituted biarylenoxy, biheteroarylenoxy, or substituted biheteroarylenoxy; and
n is an integer from 0 to about 1,000,000.

6. The organic semiconductor formulation of claim 1, wherein the OPA comprises one or more of the following compounds:

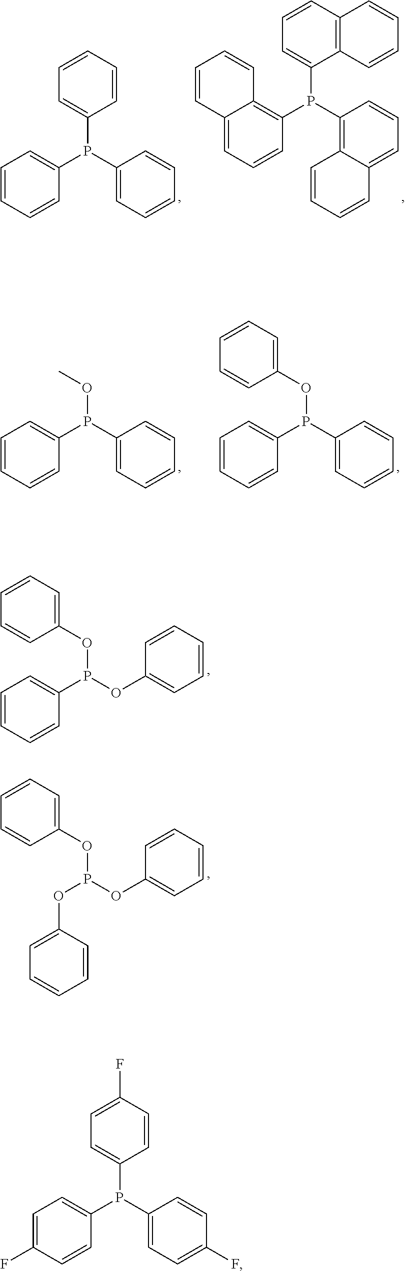

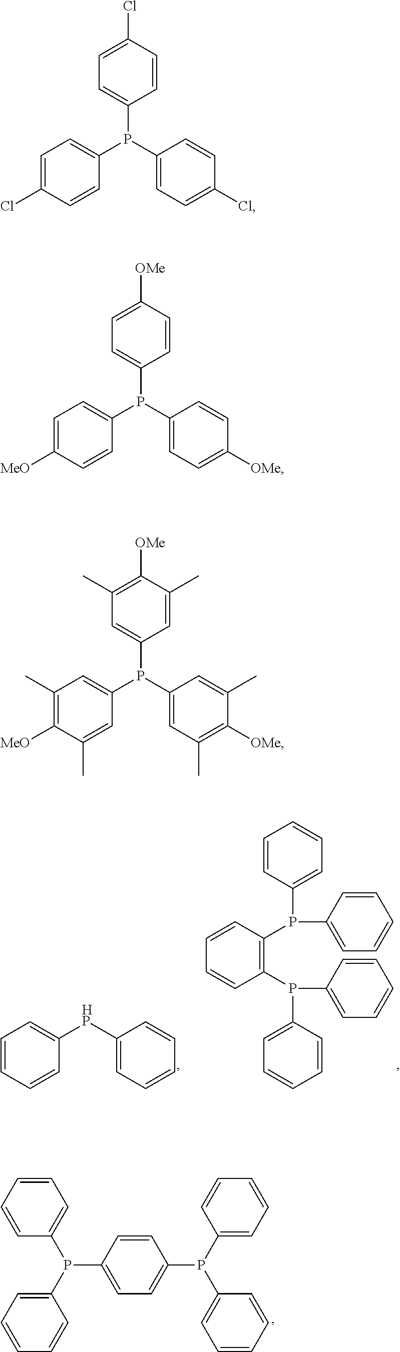

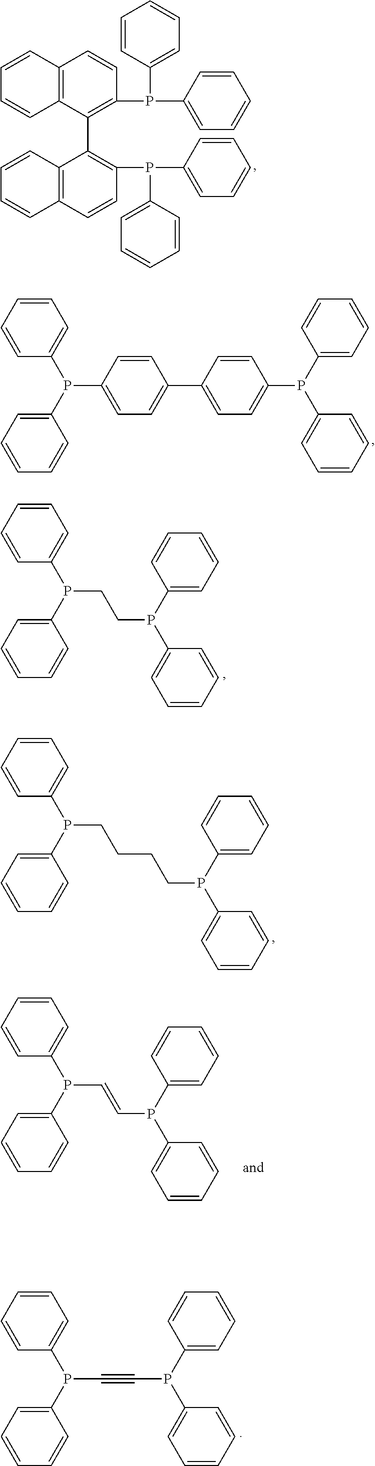

7. The organic semiconductor formulation of claim 1, wherein the OPA comprises one or more of the following moieties: 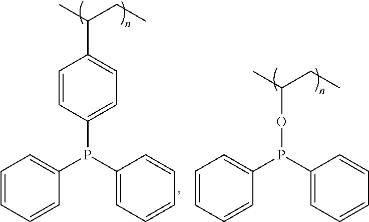
wherein n is about 1 to about 1,000,000.

8. The organic semiconductor formulation of claim 1, wherein the OPA is a polymer comprising a monomer comprising one or more moieties of the general formula (Ia): 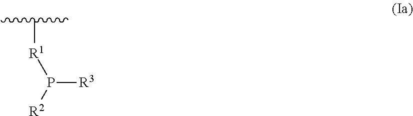
wherein: [symbol]
represents attachment to a polymer backbone;
R¹ is selected from alkylene, substituted alkylene, alkenylene, substituted alkenylene, alkynylene, substituted alkynylene, cycloalkylene, substituted cycloalkylene, arylene, substituted arylene, heteroalkylene, substituted heteroalkylene, heteroarylene, substituted heteroarylene, arylenoxy, substituted arylenoxy, heteroarylenoxy, substituted heteroarylenoxy biarylene, substituted biarylene, biheteroarylene, substituted biheteroarylene, biarylenoxy, substituted biarylenoxy, biheteroarylenoxy, or substituted biheteroarylenoxy, oxy (—O—), —S—, and —N(L)-;
R² and R³ are, independently, any suitable group, e.g., a group selected from H, hydroxyl (—OH), hydrocarbon, substituted hydrocarbon, heteroalkyl, substituted heteroalkyl heteroaryl, substituted heteroaryl, alkoxy, substituted alkoxy, aryloxy, substituted aryloxy, herteroaryloxy, substituted herteroaryloxy, haloalkyl, substituted haloaklyl, —OC(═O)L, SiL₃, —OSiL₃, —N(L)SiL₃, —C(═O)OL, —C(═O)NL₂, cyano (—CN), halogen (F, Cl, Br, or I), —NL₂, —COOH and its salt form, C(O)L, —CN, —NC, —NCO, —NCS, —OCN, —SCN, —SH, —SL, —S(═O)L, —CF₃,
or a group of formula (II) 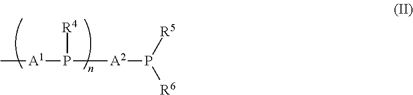
wherein R⁴, R⁵ and R⁶ are, independently, selected from any suitable group, e.g., a group selected from H, hydroxyl (—OH), hydrocarbon, substituted hydrocarbon, heteroalkyl, substituted heteroalkyl, heteroaryl, substituted heteroaryl, alkoxy, substituted alkoxy, aryloxy, substituted aryloxy, herteroaryloxy, substituted herteroaryloxy, haloalkyl, substituted haloaklyl, —OC(═O)L, SiL₃, —OSiL₃, —N(L)SiL₃, —C(═O)OL, —C(═O)NL₂, cyano (—CN), halogen (F, Cl, Br, or I), —NL₂, —COOH and its salt form, C(O)L, —CN, —NC, —NCO, —NCS, —OCN, —SCN, —SH, —SL, —S(═O)L, —CF₃, or a polymer-bound moiety selected from alkylene, substituted alkylene, alkenylene, substituted alkenylene, alkynylene, substituted alkynylene, cycloalkylene, substituted cycloalkylene, arylene, substituted arylene, heteroarylene, substituted heteroarylene, arylenoxy, substituted arylenoxy, heteroalkylene, substituted heteroalkylene, heteroarylenoxy, substituted heteroarylenoxy, biarylene, substituted biarylene, biheteroarylene, substituted biheteroarylene, biarylenoxy, substituted biarylenoxy, biheteroarylenoxy, substituted biheteroarylenoxy, oxy (—O—), —S—, and —N(L)-, or
a polymer-bound moiety selected from alkylene, substituted alkylene, alkenylene, substituted alkenylene, alkynylene, substituted alkynylene, cycloalkylene, substituted cycloalkylene, arylene, substituted arylene, heteroarylene, substituted heteroarylene, arylenoxy, substituted arylenoxy, heteroalkylene, substituted heteroalkylene, heteroarylenoxy, substituted heteroarylenoxy, biarylene, substituted biarylene, biheteroarylene, substituted biheteroarylene, biarylenoxy, substituted biarylenoxy, biheteroarylenoxy, substituted biheteroarylenoxy, oxy (—O—), —S—, and —N(L)-;
A¹ and A² are independently alkylene, substituted alkylene, alkenylene, substituted alkenylene, alkynylene, substituted alkynylene, cycloalkylene, substituted cycloalkylene, arylene, substituted arylene, heteroalkylene, substituted heteroalkylene, heteroarylene, substituted heteroarylene, heteroarylenoxy, substituted heteroarylenoxy, biarylene, substituted biarylene, biheteroarylene, substituted biheteroarylene, biarylenoxy, substituted biarylenoxy, biheteroarylenoxy, or substituted biheteroarylenoxy, oxy (—O—), —S—, and —N(L)-;
L is H, hydroxyl, hydrocarbon, substituted hydrocarbon, heteroalkyl, substituted heteroalkyl, alkoxyl, substituted alkoxy, aryloxy, substituted aryloxy, heteroaryl, substituted heteroaryl, heteroaryloxy, substituted heteroaryloxy, haloalkyl, substituted haloalkyl etc; and
n is an integer from 0 to about 1,000,000.

9. The organic semiconductor formulation of claim 1, wherein the OPA is a polymer comprising a monomer comprising one or more moieties of the general formula (Ia): 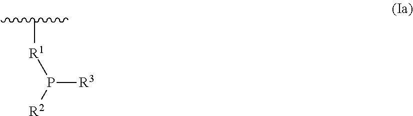
wherein: [symbol]
represents attachment to a polymer backbone;
R¹ is an oxy, alkoxy, substituted alkoxy, alkylene, substituted alkylene, alkenylene, substituted alkenylene, alkynylene, substituted alkynylene, arylene, substituted arylene, arylenoxy, or substituted arylenoxy, heteroalkylene, substituted heteroalkylene, heteroarylene, substituted heteroarylene, heteroarylenoxy, substituted heteroarylenoxy;
R² is aryl, substituted aryl, aryloxy, substituted aryloxy, heteroaryl, or substituted heteroaryl; and
R³ is any suitable substituent, for example, H, aryl, substituted aryl, heteroaryl, substituted heteroaryl, alkyl, substituted alkyl, heteroalkyl, substituted heteroalkyl, alkoxy, substituted alkoxy, aryloxy or substituted aryloxy; or
R³ is a group of formula (II): 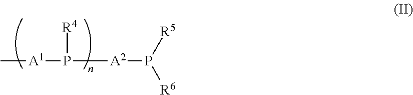
wherein R⁴, R⁵ and R⁶ are independently aryl, substituted aryl, aryloxy, substituted aryloxy, heteroaryl or substituted heteroaryl; and
A¹ and A² are independently alkylene, substituted alkylene, alkenylene, substituted alkenylene, alkynylene, substituted alkynylene, cycloalkylene, substituted cycloalkylene, arylene, substituted arylene, heteroalkylene, substituted heteroalkylene, heteroarylene, substituted heteroarylene, biarylene, substituted biarylene, biheteroarylene, substituted biheteroarylene, biarylenoxy, substituted biarylenoxy, biheteroarylenoxy, or substituted biheteroarylenoxy; and
n is an integer from 0 to about 1,000,000.

10. The organic semiconductor formulation of claim 1, wherein the OPA comprises a polymer comprising one or more repeat units selected from the group consisting of: 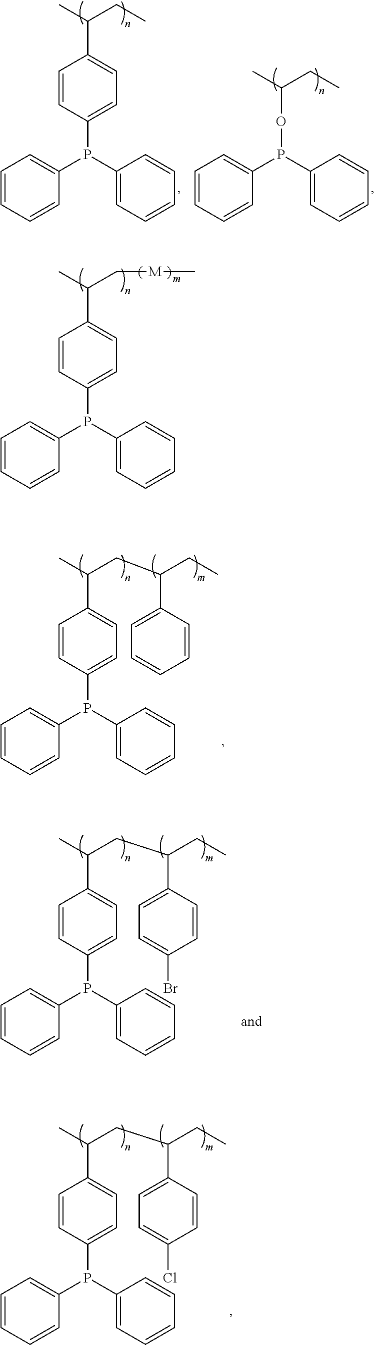
wherein
M is alkylene, methyl acrylate, methyl methacrylate, or any suitable polymer moiety.
n is an integer 1 to about 10,000
m is an integer from 0 to about 5,000; and the number of repeat units in the polymer is between about 5 to about 10,000.

11. The organic semiconductor formulation of claim 1 wherein the where the organic semiconductor has a LUMO energy level of −3 eV or lower.

12. The organic semiconductor formulation of claim 1, wherein the where the organic semiconductor is an ambipolar, n-type or p-type organic polymer semiconductor.

13. The organic semiconductor formulation of claim 1, wherein the organic semiconductor is an organic polymer semiconductor.

14. The organic semiconductor formulation of claim 1, wherein the organic semiconductor is selected from one or more of the following structures: 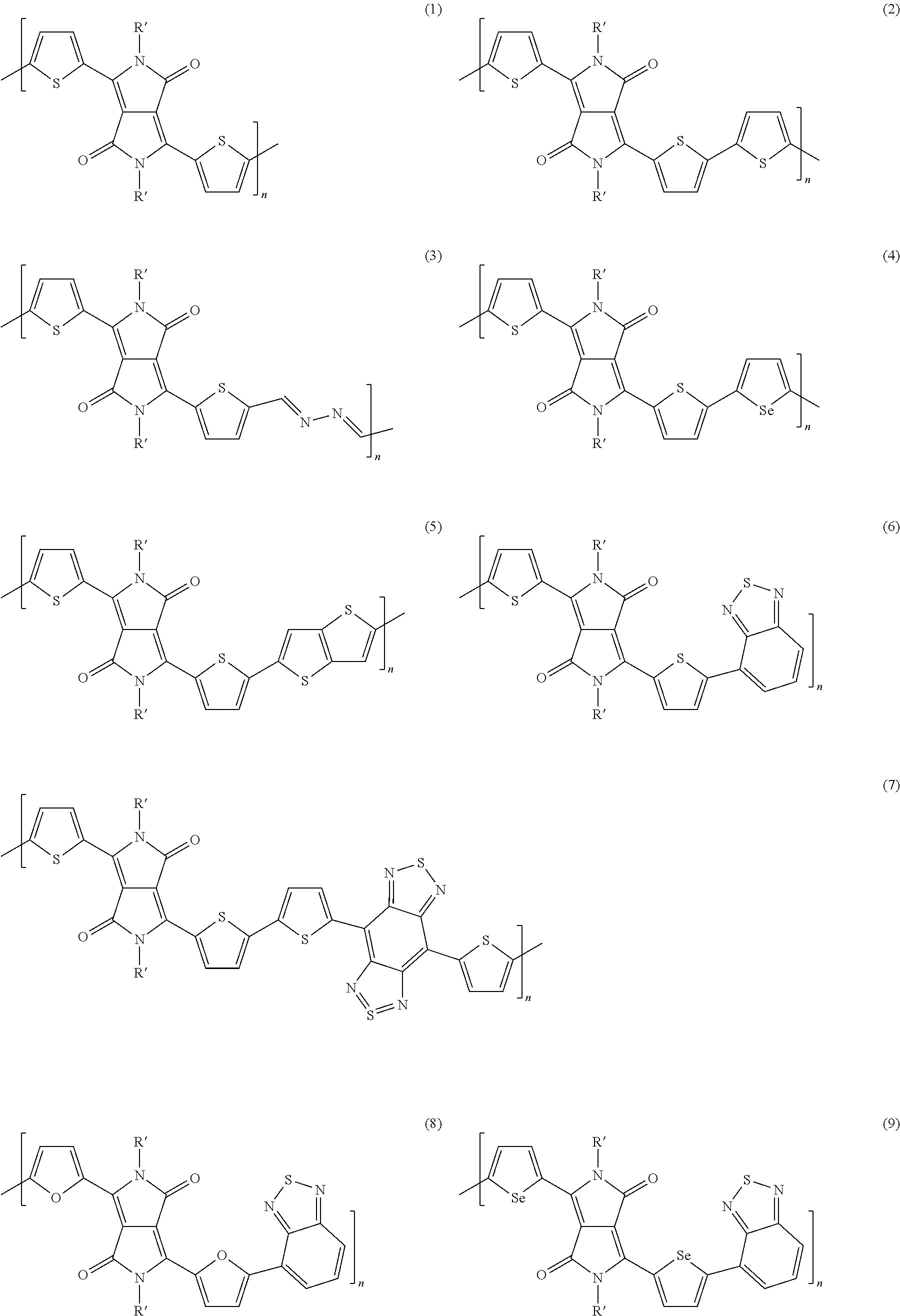 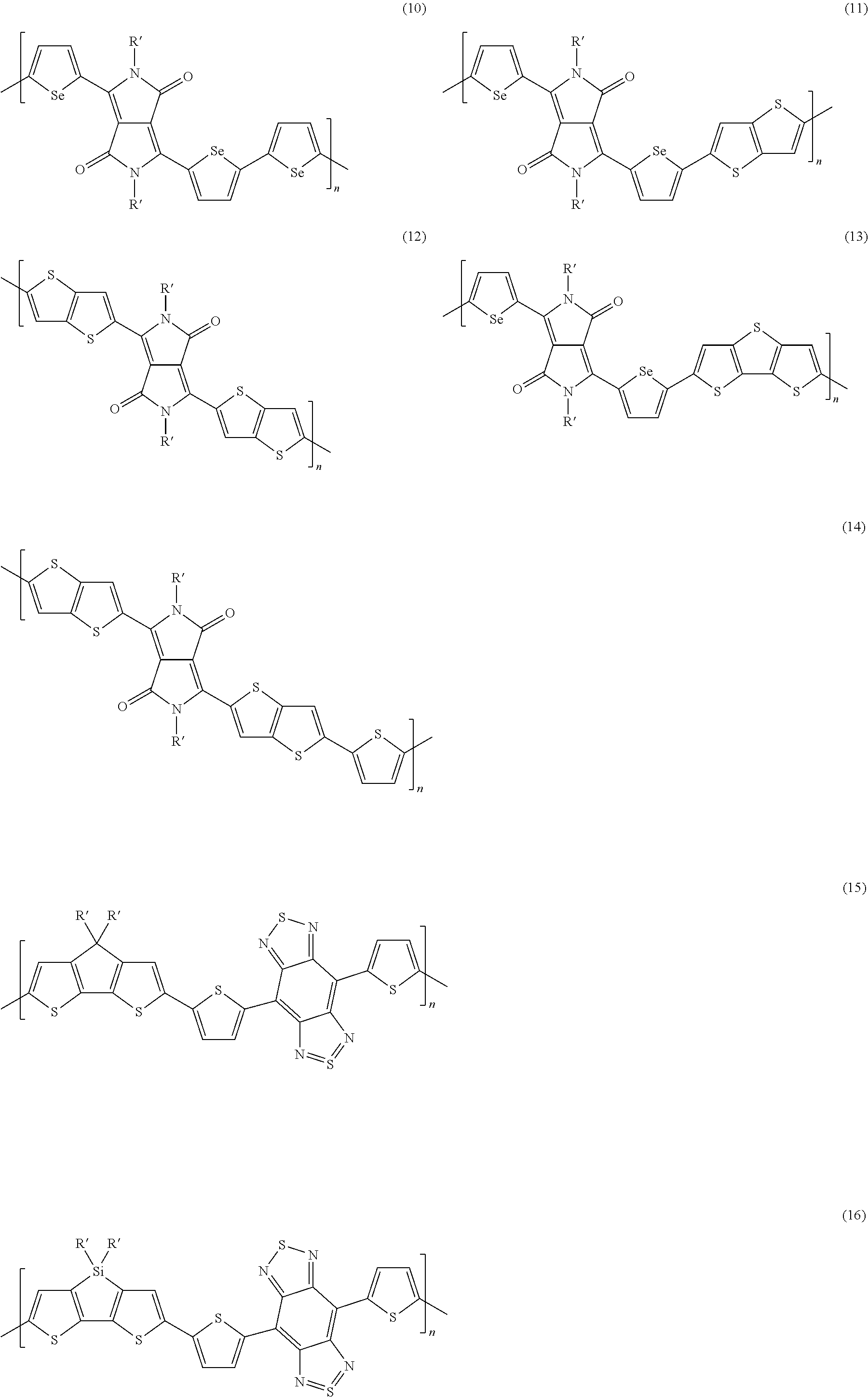 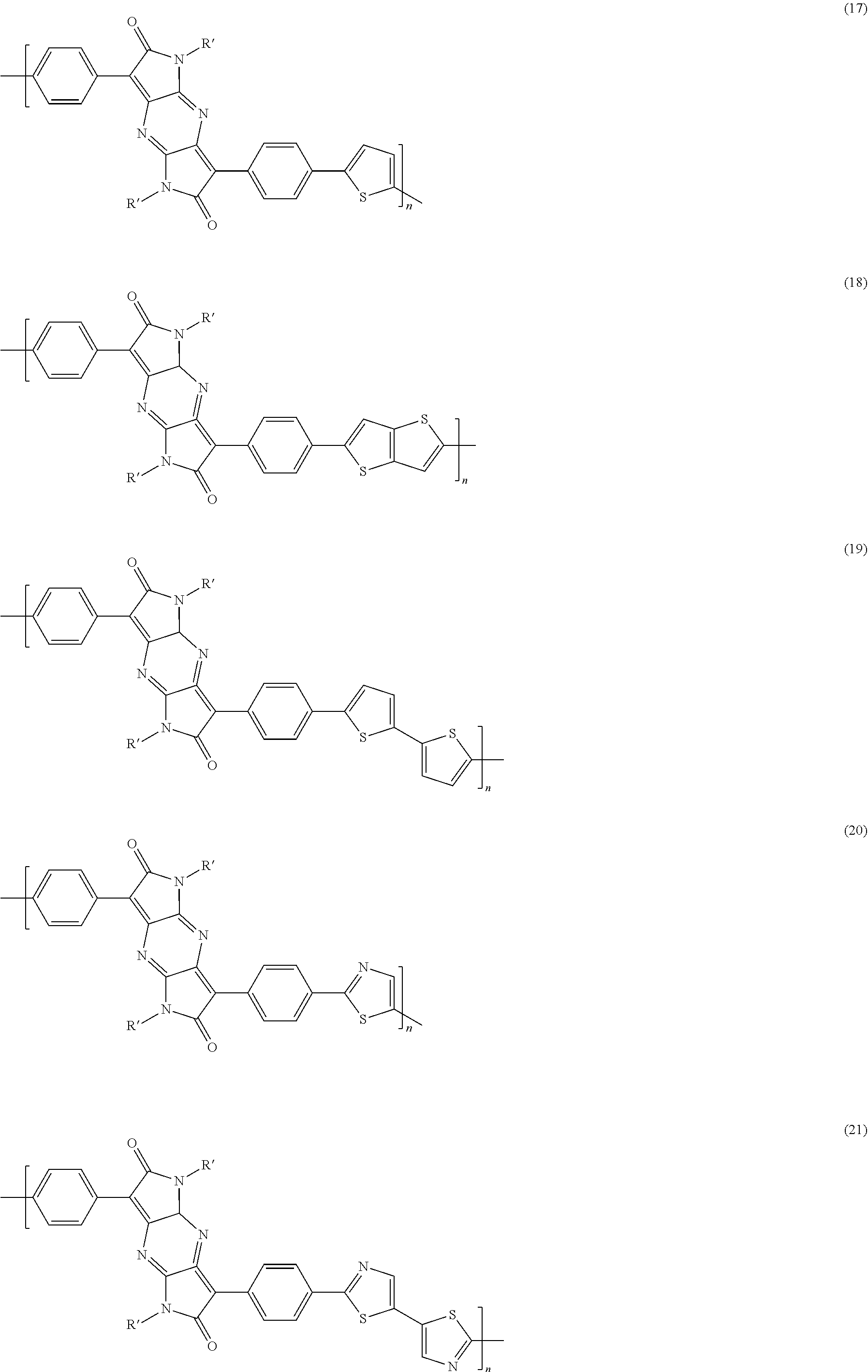 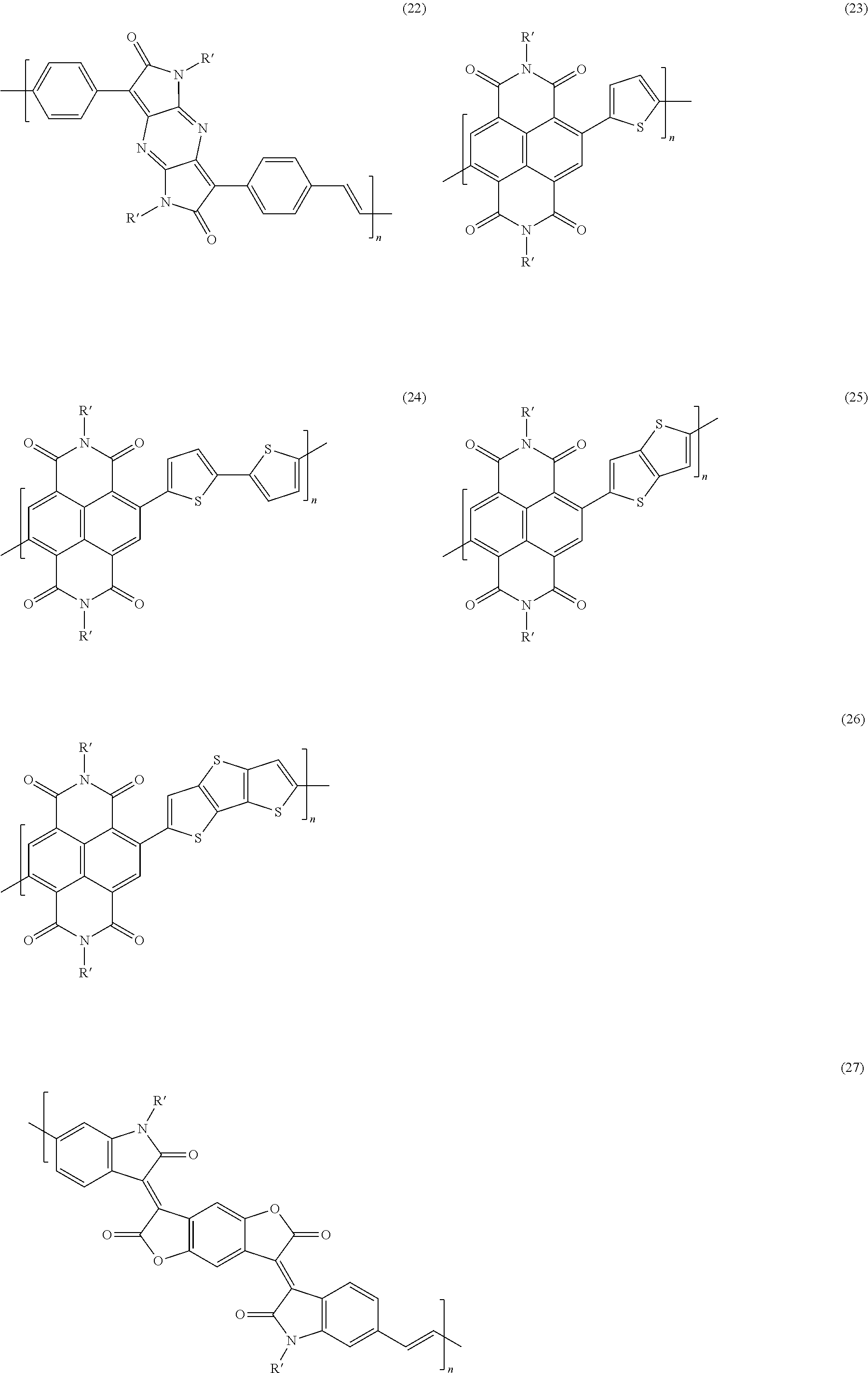 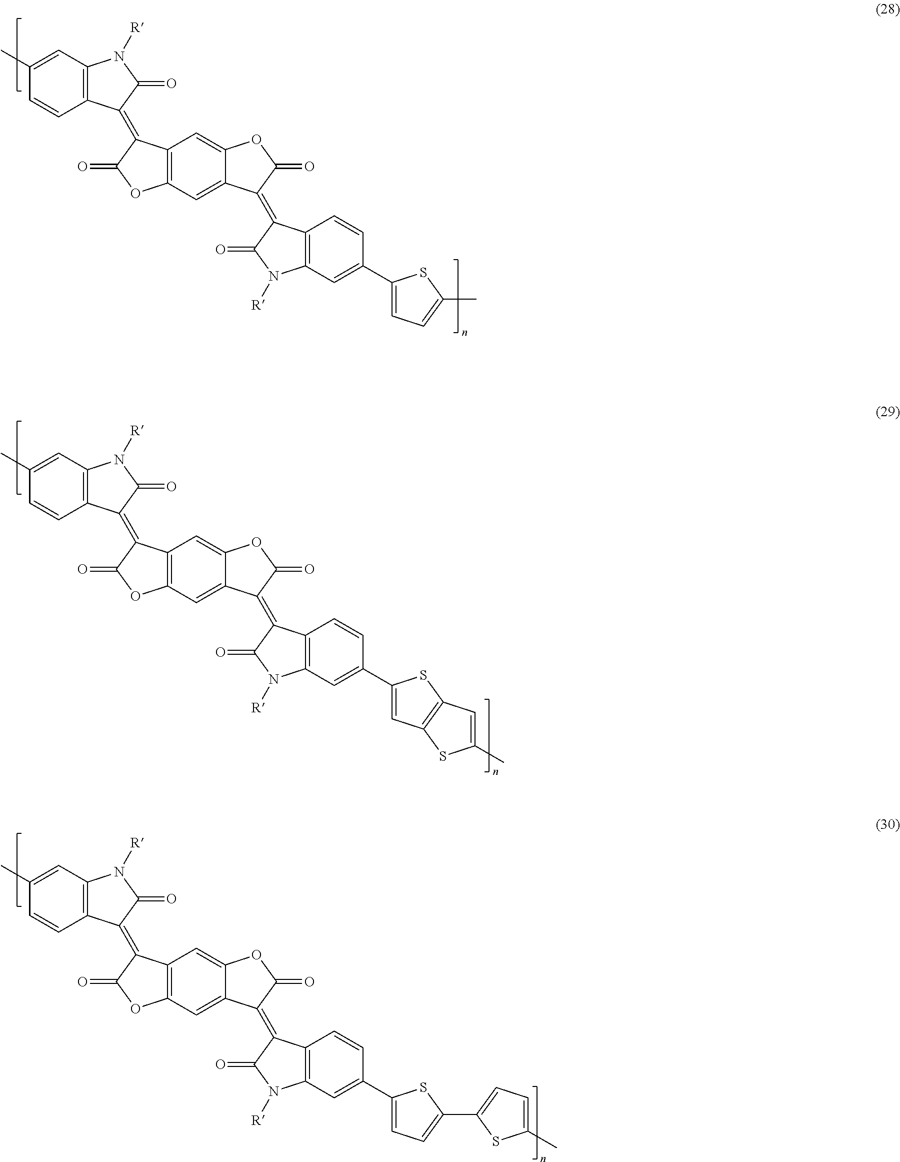 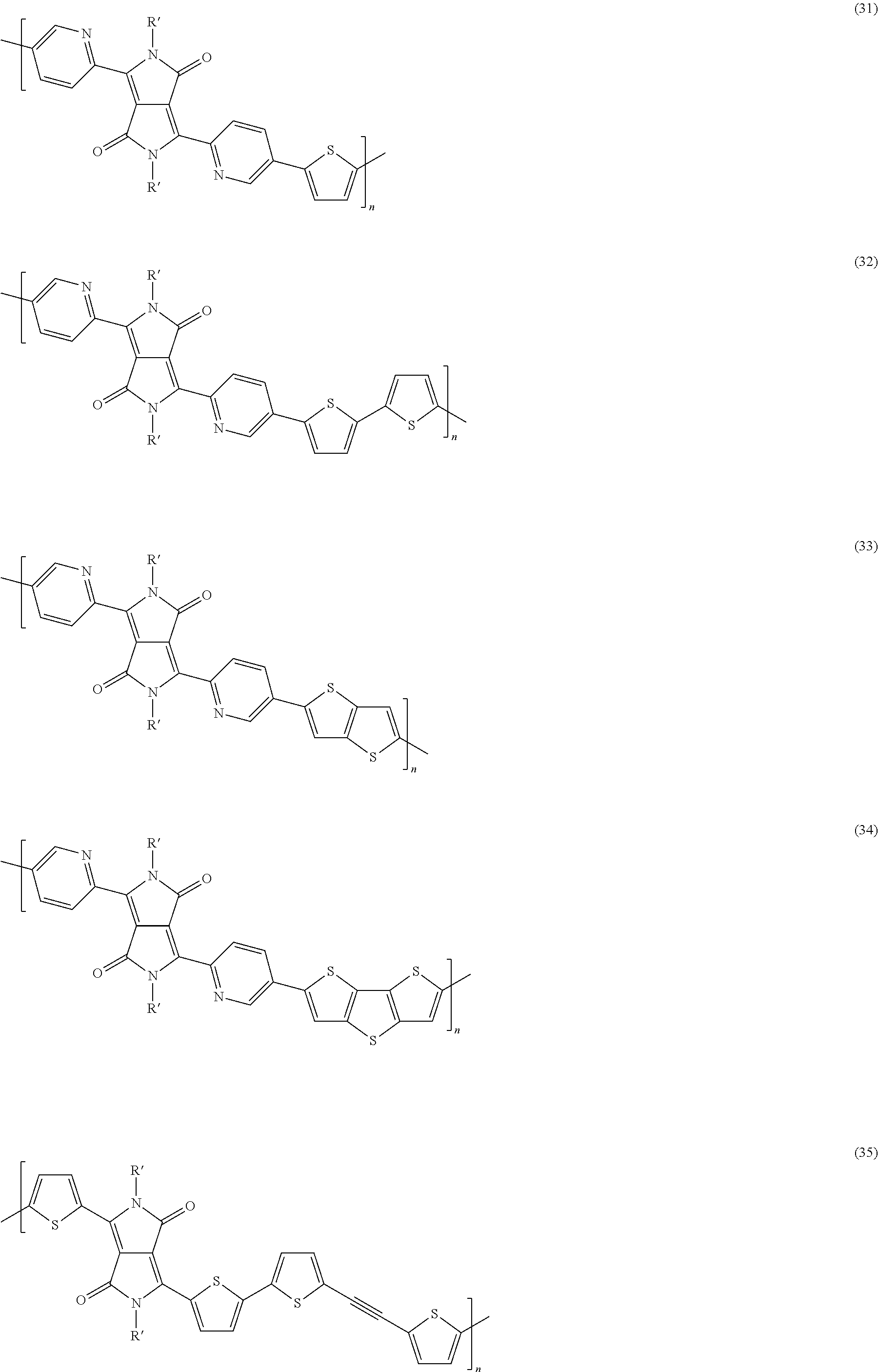 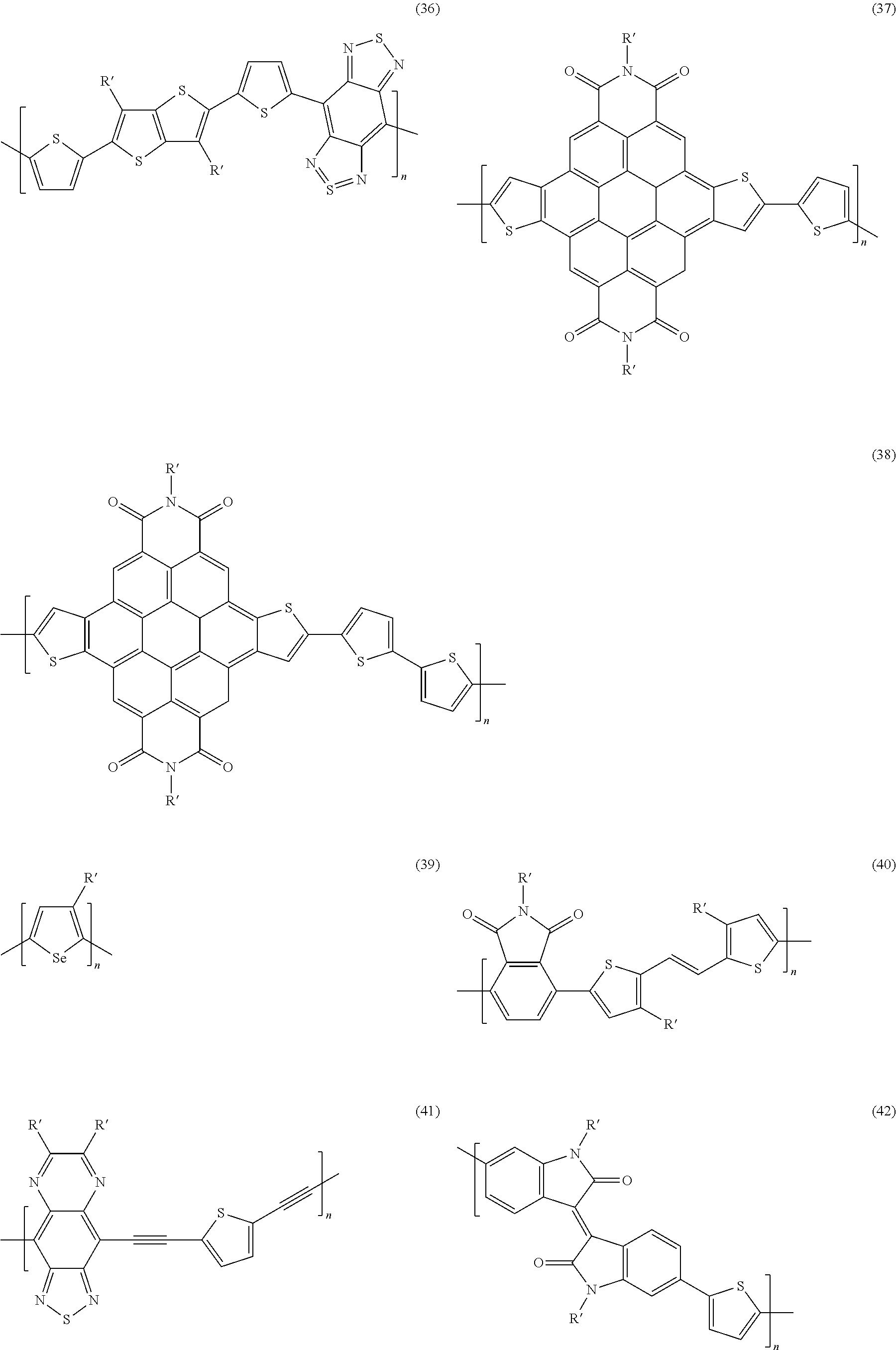 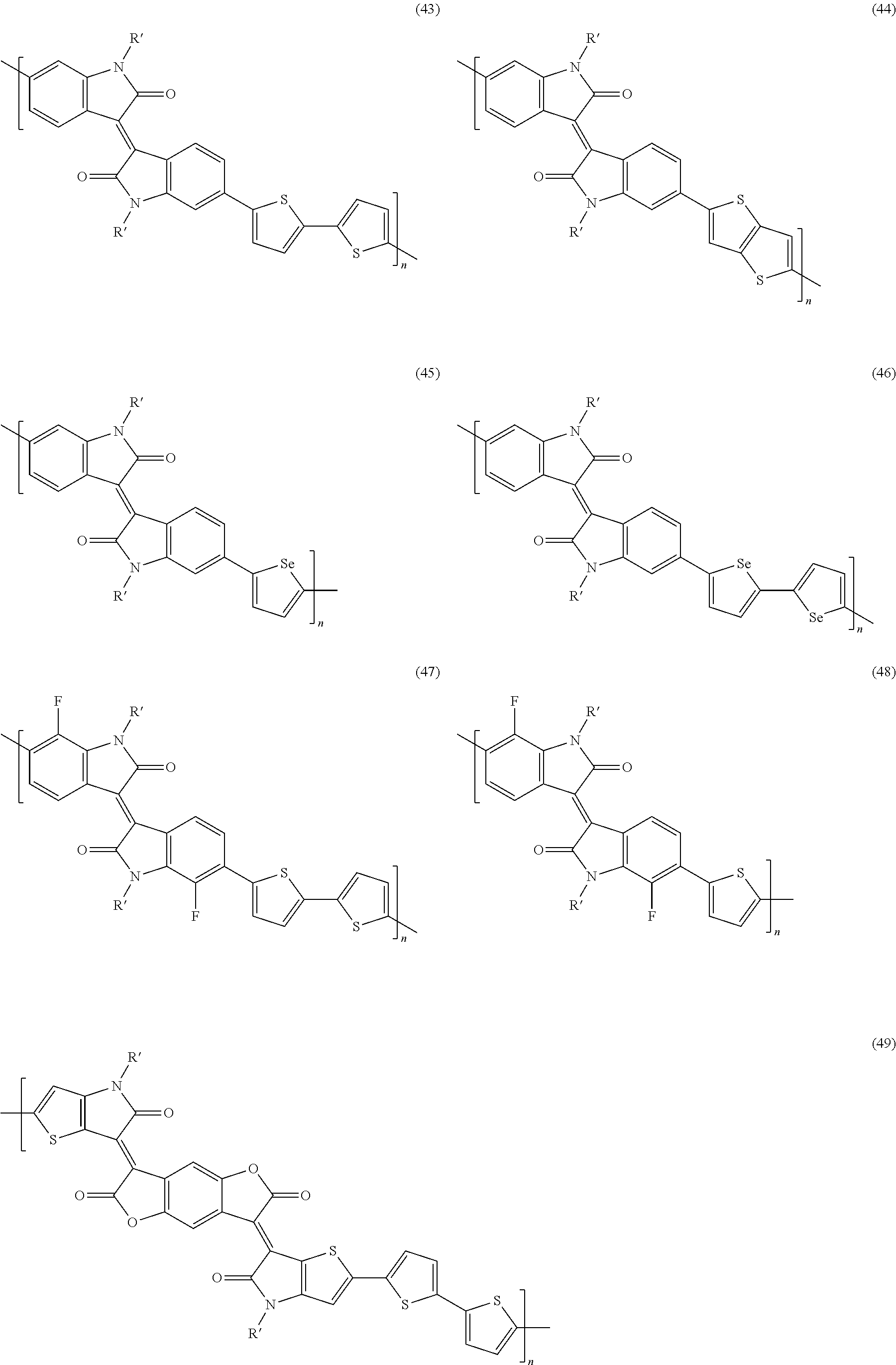 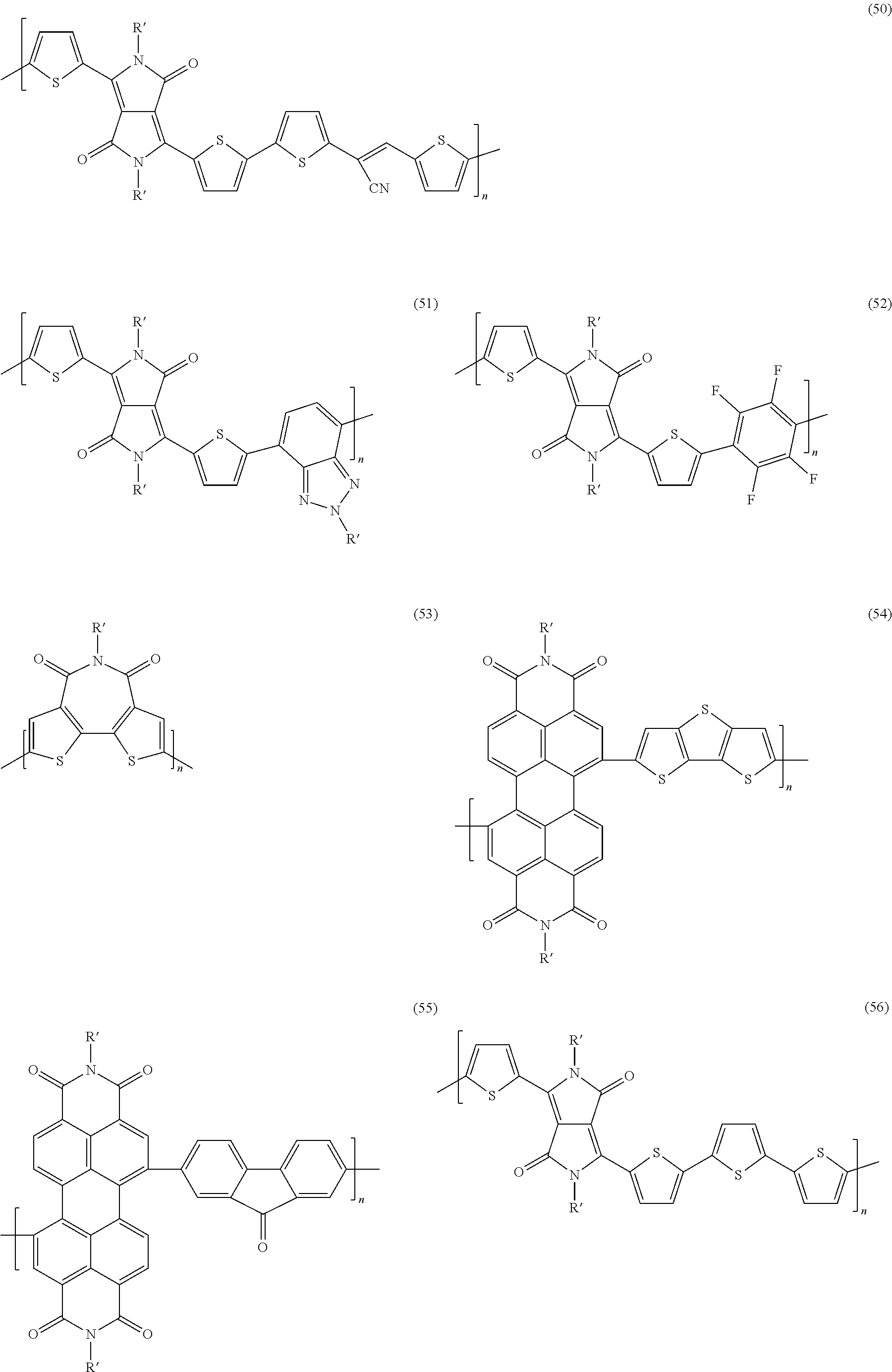 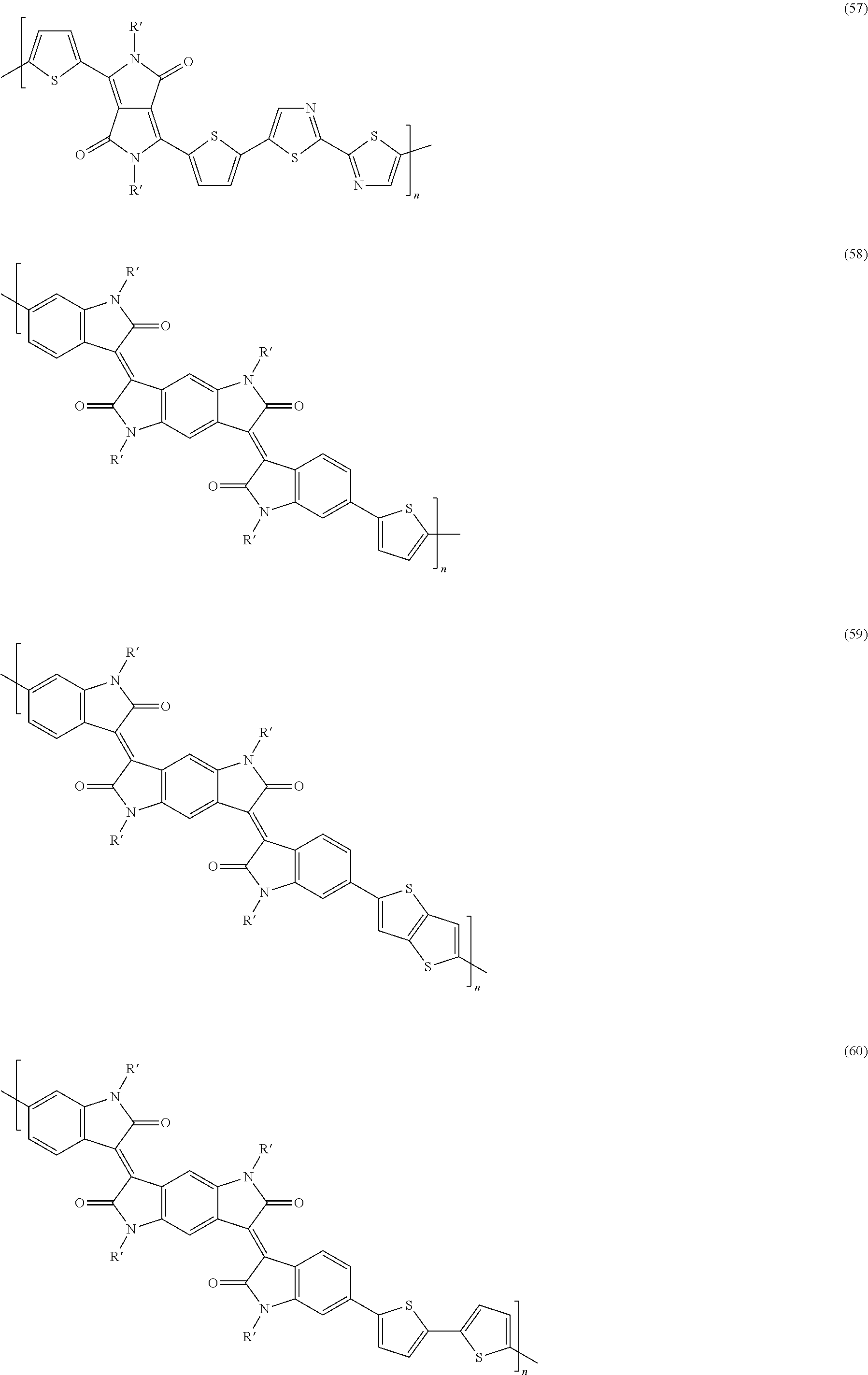 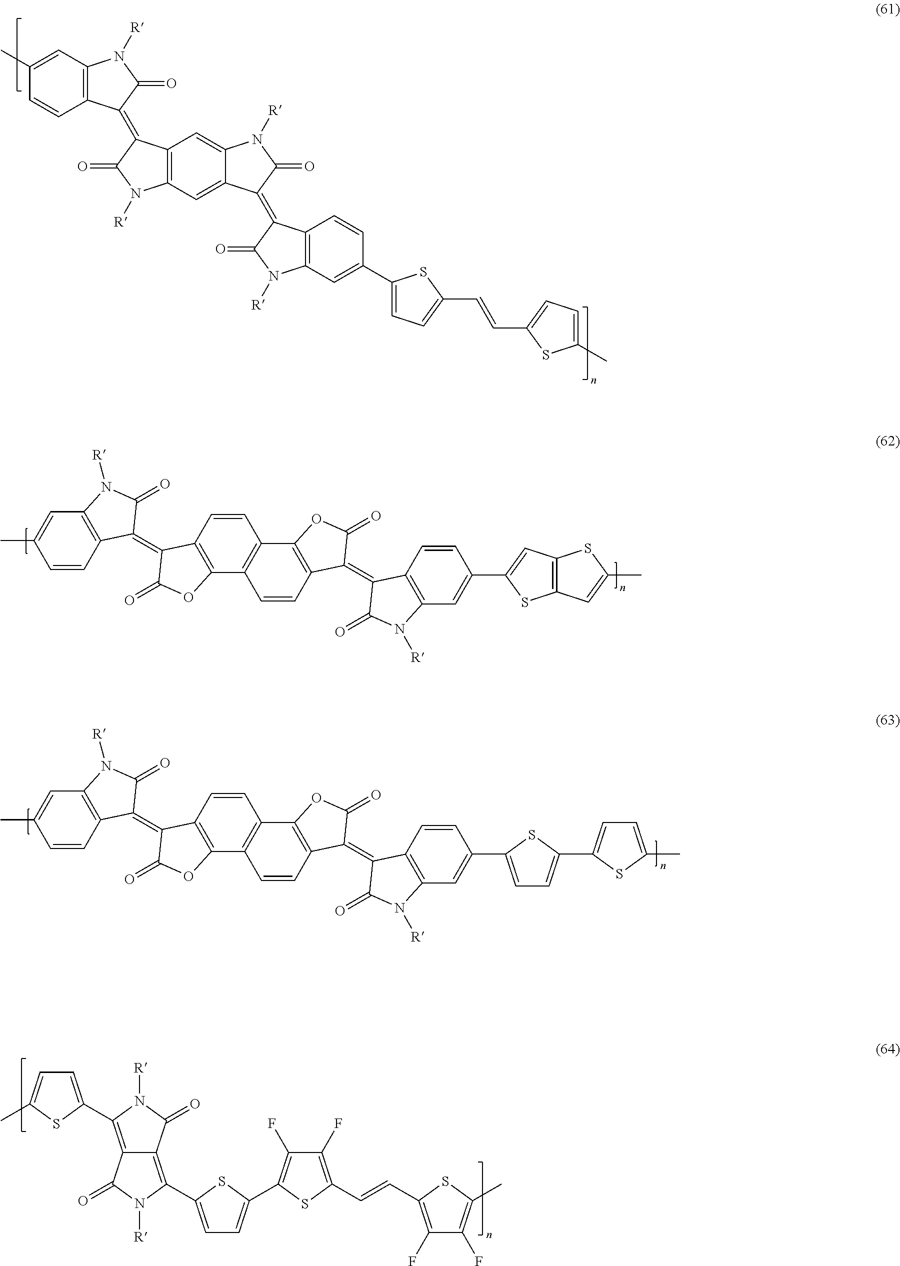 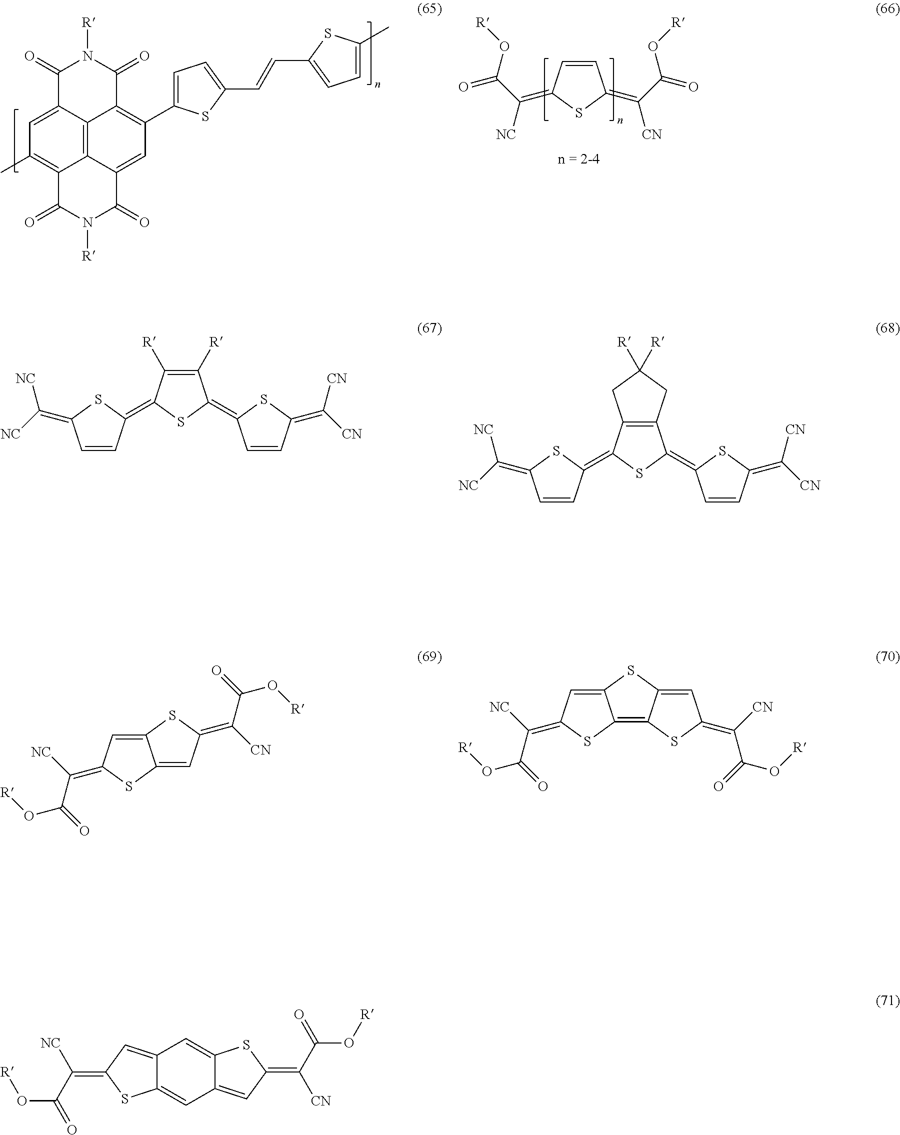
wherein
R′ is independently selected from H, hydroxyl (—OH), hydrocarbon, substituted hydrocarbon, heteroaryl, substituted heteroaryl, heteroalkyl, substituted heteroalkyl, alkoxy, substituted alkoxy, aryloxy, substituted aryloxy, herteroaryloxy, substituted herteroaryloxy, haloalkyl, substituted haloaklyl, —OC(═O)L, SiL₃, —OSiL₃, —N(L)SiL₃, —C(═O)OL, —C(═O)NL₂, imide, cyano (—CN), halogen (F, Cl, Br, or I), —NL₂, —COOH and its salt form, C(O)L, —CN, —NC, —NCO, —NCS, —OCN, —SCN, —SH, —SL, S(═O)L, —SO₃H and its salt form, —SO₂L, —NO₂, —CF₃, —SF₅, a polymer-bound moiety selected from alkylene, substituted alkylene, alkenylene, substituted alkenylene, alkynylene, substituted alkynylene, cycloalkylene, substituted cycloalkylene, arylene, substituted arylene, heteroalkylene, substituted heteroalkylene, heteroarylene, substituted heteroarylene, arylenoxy, substituted arylenoxy, heteroarylenoxy, substituted heteroarylenoxy, biarylene, substituted biarylene, biheteroarylene, substituted biheteroarylene, biarylenoxy, substituted biarylenoxy, biheteroarylenoxy, substituted biheteroarylenoxy, oxy (—O—), —S—, and —N(L)-; or any other suitable group;
L is H, hydroxyl, hydrocarbon, substituted hydrocarbon, alkoxyl, substituted alkoxy, aryloxy, substituted aryloxy, heteroalkyl, substituted heteroalkyl, heteroaryl, substituted heteroaryl, heteroaryloxy, substituted heteroaryloxy, haloalkyl, substituted haloalkyl, or a group of formula (II) as defined above, etc.; and
n is the number of repeat units and represents an integer from about 1 to about 1,000,000.

15. A semiconducting layer comprising an n-type organic semiconductor formulation, the formulation comprising:
an organic semiconductor; and
an organic phosphorous-containing additive capable of enhancing the electron transport performance of the organic semiconductor.

16. A method of enhancing n-type performance of an organic semiconductor, comprising mixing the OSC with an organic phosphorous-containing additive (OPA) capable of enhancing the n-type performance of the organic semiconductor to thereby form an n-type semiconductor formulation, whereby the n-type performance of the organic semiconductor is enhanced.

17. An electronic device, comprising a semiconductor layer comprising:
an organic semiconductor; and
an organic phosphorous-containing additive capable of enhancing the n-type performance of the organic semiconductor.

18. An organic thin film transistor comprising: a dielectric layer; a gate electrode; a semiconductor layer; a source electrode; a drain electrode, and a substrate, wherein the semiconductor layer comprises an n-type organic semiconductor formulation comprising:
an organic semiconductor; and
an organic phosphorous-containing additive capable of enhancing the n-type performance of the organic semiconductor.

19. A method for producing an organic semiconductor formulation comprising an organic semiconductor (OSC) and an organic phosphorous-containing additive (OPA) capable of enhancing the n-type performance of the organic semiconductor, the method comprising:
a) mixing an OPA with an OSC optionally in the presence of a liquid or solvent (the first solvent); and
b) optionally removing the first solvent by any suitable method such as evaporation or distillation; and
c) optionally adding a second same or different solvent to dissolve or disperse the organic semiconductor formulation to any desirable concentration.
